(19) United States
(12) Patent Application Publication
(10) Pub. No.: US 2025/0006726 A1
(43) Pub. Date: Jan. 2, 2025

(54) SERIAL INTERFACE PROVIDING ELECTROSTATIC DISCHARGE PROTECTION

(71) Applicant: Intel Corporation, Santa Clara, CA (US)

(72) Inventors: Krzysztof Domanski, Neubiberg (DE); Harshit Dhakad, Bangalore (IN)

(73) Assignee: Intel Corporation, Santa Clara, CA (US)

(21) Appl. No.: 18/216,442

(22) Filed: Jun. 29, 2023

(51) Int. Cl. H01L 27/02; H01L 27/06

(52) U.S. Cl. CPC H01L 27/0288; H01L 27/0255; H01L 27/0266; H01L 27/0635

(57) ABSTRACT

An integrated circuit (IC) device comprises a conductive contact at a surface of the IC device. A resistive element is coupled between the conductive contact and first circuitry. Second circuitry is coupled between the resistive element and the conductive contact. The second circuitry is further coupled with a supply line and comprises at least one of a diode or a power clamp. The resistive element is disposed in a first metallization layer of the IC device. A first dielectric layer is adjacent to the first metallization layer. A second metallization layer is adjacent to the first dielectric layer. A height of the first dielectric layer and the second metallization layer is a first distance. A zone overlaps the resistive element, and extends a second distance away from the resistive element. The zone is free of conductive material and the second distance is greater than the first distance.

### BACKGROUND

### 1. Technical Field

This disclosure generally relates to electrostatic discharge protection for circuitry and more particularly, but not exclusively, to electrostatic discharge protection for circuitry employing a high-frequency interface.

### 2. Background Art

Integrated circuits (ICs) are susceptible to damage from exposure to excess charge, such as that generated during an electrostatic discharge (ESD) event. In particular, ICs can be exposed to electrostatic charge events during manufacturing, packaging, attaching the IC to a circuit board, and in other situations. The susceptibility of an IC to damage can be tested with a device that simulates an ESD event. An ESD event can be simulated using a charge device model (CDM), a human body model (HBM), or another model. The CDM simulates a contact, pad, or pin of the IC being charged or discharged with respect to a metal surface, such as what might occur during manufacturing. A CDM testing device charges the device under test (DUT) to a charging voltage, e.g., 250V, then discharges the DUT to a pad or pin of the IC, which creates a current of several amperes. An HBM testing device simulates the charge or discharge to an IC that might occur when an IC pad or pin is touched by a human and another pin is grounded. HBM testing creates a current of 0.75 A (at 1 KV). The duration of the pulse and the slew rate are different for HBM and CDM.

A high-frequency (HF) interface may operate in frequencies in the range of several GHz. Devices with HF interfaces can use circuitry with CMOS FinFET technologies, which can be damaged if subject to overvoltage, e.g., an ESD event at the interface. A FinFET is a type of field effect transistor (FET) that includes a vertical fin instead of being entirely planar.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. Certain figures may be shown in an idealized fashion in order to aid understanding, such as when structures are shown having straight lines, sharp angles, and/or parallel planes or the like that under real-world conditions would likely be significantly less symmetric and orderly. In the figures:

FIG. 1 is a schematic diagram of an IC device comprising interface circuitry and ESD protection circuitry employing first, second, and third supply lines, in accordance with some embodiments;

FIG. 2 is a schematic diagram of an IC device comprising interface circuitry and ESD protection circuitry employing first, second, and third supply lines, in accordance with some embodiments;

FIG. 3 is a schematic diagram of an IC device comprising interface circuitry and ESD protection circuitry employing first, second, third, and fourth supply lines, in accordance with some embodiments;

FIG. 4 is a schematic diagram of an IC package comprising interface circuitry and ESD protection circuitry employing first, second, and third supply lines, in accordance with some embodiments;

FIG. 5 is a schematic diagram of an IC package comprising interface circuitry and ESD protection circuitry employing first, second, and third supply lines, in accordance with some embodiments;

FIG. 6 is a schematic diagram of an IC device comprising interface circuitry and ESD protection circuitry employing first, second, and third supply lines, in accordance with some embodiments;

FIG. 7 is a schematic diagram of an IC device comprising interface circuitry and ESD protection circuitry employing first, second, and third supply lines, in accordance with some embodiments;

FIG. 8 is a schematic diagram of an IC device comprising interface circuitry and ESD protection circuitry that includes a variable resistive element, according to some embodiments;

FIG. 9 is a schematic diagram of an IC device comprising interface circuitry and ESD protection circuitry that includes a variable resistive element, according to some embodiments;

FIG. 10 is a schematic diagram of an IC device comprising interface circuitry and ESD protection circuitry that includes a variable resistive element, according to some embodiments;

FIG. 11A is a cross-sectional illustration of an IC die comprising a resistive element in a region of the IC die, according to some embodiments;

FIG. 11B is a cross-sectional, enlarged illustration of the region of the IC die in FIG. 11A, according to some embodiments;

FIG. 11C is a cross-sectional illustration of the region of the IC die in FIG. 11B along line A-A,′ according to some embodiments;

FIG. 11D is a cross-sectional illustration of the region of the IC die in FIG. 11B along line B-B,′ according to some embodiments;

FIGS. 12A and 12B are graphs of illustrating voltages over a range of current values applied to a resistive element from which resistive values for high and low current values are determined, according to some embodiments;

FIG. 13 is a graph illustrating transmission line pulse (TLP) measurements of a stand-alone high-frequency switch with different gate and bulk connections, according to some embodiments;

FIG. 14 is a functional block diagram of an electronic computing device, in accordance with some embodiments; and

FIG. 15 illustrates a mobile computing platform and a data server machine employing a composite IC chip structure, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with each of the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

ICs described herein may include logic, memory, or other any other type of known circuitry. In some embodiments, an IC may comprise any type of semiconductor device. In one embodiment, the IC comprises a processing system or device. For example, an IC may comprise a microprocessor or a graphics processor. The IC can perform instructions from any number of processor architectures having any number of instruction formats. In one embodiment, the IC may employ an “x86” instruction set architecture, as used by Intel Corporation. However, in other embodiments, the processor may perform instructions from other architectures or from other processor designers. For example, in some embodiments, the IC may employ a reduced instruction set computer (RISC) architecture. In another embodiment, the IC comprises a memory device. According to a further embodiment, the IC comprises a system-on-chip (SoC). In yet another embodiment, the IC may include digital circuitry, analog circuitry, or a combination of both analog and digital circuitry.

The term “metallization” generally refers to metal layers formed over and through a dielectric material of a package substrate. The metal layers are generally patterned to form metal structures such as traces and bond pads. The metallization of a package substrate may be confined to a single layer or may be provided in multiple layers separated by layers of dielectric. A dielectric layer may comprise any suitable dielectric material (e.g., polymer materials, silicon dioxide (Si02), silicon nitride (Si3N4), etc.) and may be formed by any suitable technique (e.g., by deposition, lamination, plasma-enhanced chemical vapor deposition (PECVD), etc.) In some embodiments, a dielectric material may be dielectric/organic materials, resins, epoxies, polymer adhesives, silicones, acrylics, polyimides, cyanate esters, thermoplastics, and/or thermosets. A metallization layer may comprise any suitable electrically conductive metal (e.g., copper, aluminum, silver, etc.), and may be deposited by any suitable technique (e.g., plating processes, such as electroplating and electroless plating). Further, a metal layer may be patterned to form any suitable number and configuration of traces, power planes, ground planes, and other conductors to facilitate the routing of power and input/output (I/O) signals. In embodiments, a layer may be coupled with a power supply, e.g., a power plane or other power conductor in a metallization layer may be coupled with a power supply. In some embodiments, an IC die may include a redistribution layer.

A high-speed interface operates at high frequencies (HF) in the Gigahertz range, e.g., 4 GHZ. One example of a device that operates at HF is a 112/224GBps serializer-deserializer circuitry (SERDES). Devices with HF interfaces require low capacitance and resistance at the I/O pad used to transmit or receive a signal. In addition, devices with HF interfaces can use circuitry coupled with an I/O pad that uses CMOS FinFET technologies. CMOS FinFETs (or other transistor architectures such as nanowires, nanoribbons, etc.) can be damaged if subject to overvoltage. Accordingly, ESD protection is generally required at HF interfaces, and the ESD protection should not introduce a large capacitance or resistance. However, if known methods for ESD protection are employed at a HF interface, the capacitive load or series resistance, or both, at the I/O pad are typically too high. With known methods for ESD protection, it is typically impossible for a HF interface to meet CDM and HBM targets and simultaneously satisfy load capacitance constraints.

Embodiments are directed to ESD protection circuitry coupled with an I/O pad and a local supply voltage. Embodiments are particularly suitable for HF receivers and transmitters, but may be used with circuitry performing other functions or operating at lower frequencies than HF. In embodiments, ESD protection circuitry comprises one or more stages, each stage being coupled with a “local” supply voltage. The local supply voltage is distinct from the supply voltage coupled with a HF switch or other victim. The term “victim,” as used herein, refers to circuitry susceptible to damage by an ESD event or being provided with ESD protection. An advantage of embodiments disclosed herein is that ESD protection may be provided to a victim without introducing a large capacitance or resistance.

ESD protection circuitry coupled with a local supply voltage drives the major part of the current during an ESD event. In some embodiments, the supply voltage provided to the victim is decoupled by a resistor from the local supply voltage provided to the ESD protection circuitry. In an embodiment, the decoupling resistor may be about 1k Ohm. Embodiments may include a clamping network coupled with the same supply voltage as the victim. The clamping network drives only residual displacement current transferred by a decoupling capacitor. The residual displacement current can be shunted more efficiently since the supply voltage of the clamping network is decoupled from primary discharge path.

An advantage of embodiments is that voltage stress to the gate oxide of a HF switch may be reduced. In addition, smaller diodes can be used in ESD protection circuitry. Use of smaller diodes reduces the capacitive load at a HF interface.

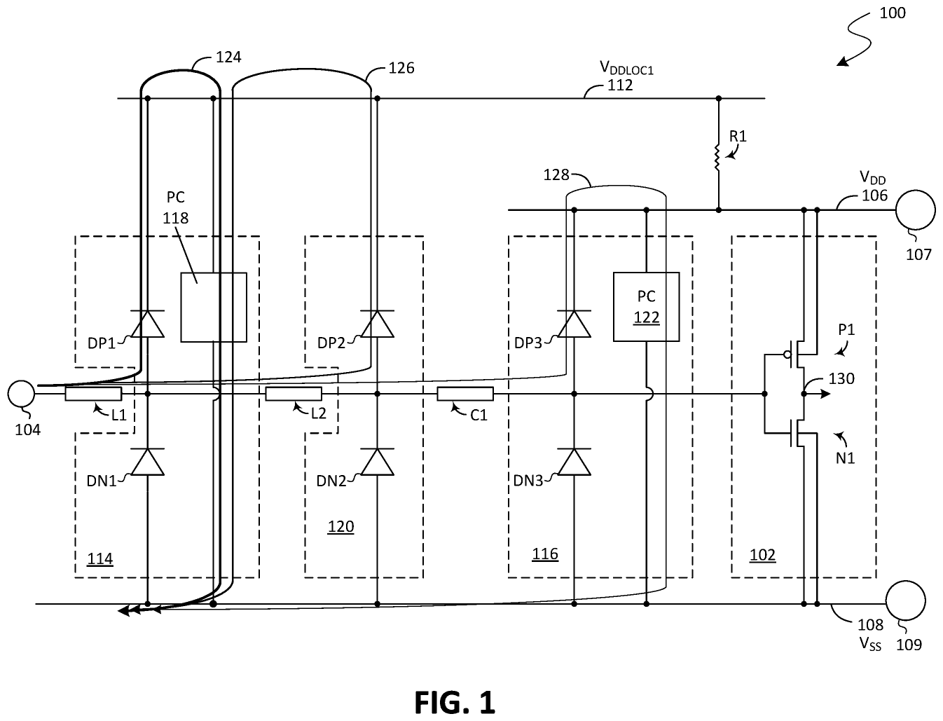

FIG. 1 is a schematic diagram of an IC device comprising interface circuitry and ESD protection circuitry employing first, second, and third supply lines, in accordance with some embodiments. IC device 100 comprises first circuitry 102 coupled with a first conductive contact 104. First circuitry 102 is also coupled between a first supply line 106 and a second supply line 108. First circuitry 102 may be a “victim” or “target,” which is to be protected by ESD protection circuitry. First circuitry 102 may be any circuitry or structure to be protected from an ESD event. In various embodiments, first circuitry 102 is an inverter, a HF switch, an input to a high-speed I/O (HISO) receiver, or an input to a low noise amplifier (LNA). First circuitry 102 may comprise a serial interface. The first supply line 106 is coupled to provide a supply voltage V_{DD} and the second supply line 108 is coupled to provide a ground reference voltage V_{SS}. The second supply line 108 may also be referred to herein as a ground reference voltage line. The first supply line 106 may be coupled with a second conductive contact 107 and the second supply line 108 may be coupled with a third conductive contact 109. In some embodiments, the first conductive contact 104 may be an I/O pad, the second conductive contact 107 may be a power supply pad (V_{DD}), and the third conductive contact 109 may be a ground reference voltage (V_{SS}) pad. In embodiments, first conductive contact 104 is an I/O pad for receiving a signal or transmitting a signal.

A resistive element R1 is coupled between the first supply line 106 and a third supply line 112. The third supply line 112 may be referred to herein as a local supply voltage V_{DDLOC1}. In some embodiments, the resistive element R1 comprises one or more metal conductive paths or traces in one or more metallization layers of the IC device 100. In some embodiments, the resistive element R1 comprises a polycrystalline silicon material. In embodiments, the resistive element R1 has a resistance value of at least 500 ohms. In some embodiments, the only coupling between first supply line and the third supply line is the resistive element R1.

As illustrated in FIG. 1, first ESD protection circuitry 114 is coupled with the first conductive contact 104. First ESD protection circuitry 114 is also coupled between the third supply line 112 (V_{DDLOC1}) and the second supply line 108 (V_{SS}). The first ESD protection circuitry 114 may include a variety of different components in different embodiments. In the example shown in FIG. 1, first ESD protection circuitry 114 includes a diode DP1 coupled between the first conductive contact 104 and the third supply line 112, and a diode DN1 coupled between the first conductive contact 104 and the second supply line 108. The diode DP1 may be a p-type type diode and the diode DN1 may be an n-type type diode. The cathode of the diode DP1 is coupled with the third supply line 112 while the anode of is coupled with first conductive contact 104. The cathode of the diode DN1 is coupled with first conductive contact 104 while the anode of is coupled with the second supply line 108. First ESD protection circuitry 114 may be coupled with the conductive contact 104 by component L1. In various, embodiments, the component L1 may be an inductor, a capacitor, or a resistor.

In some embodiments, the first ESD protection circuitry 114 includes a power clamp PC 118 coupled between the third supply line 112 and the second supply line 108. PC 118 may include a variety of different components in different embodiments. PC 118 may comprise any power clamp component described herein.

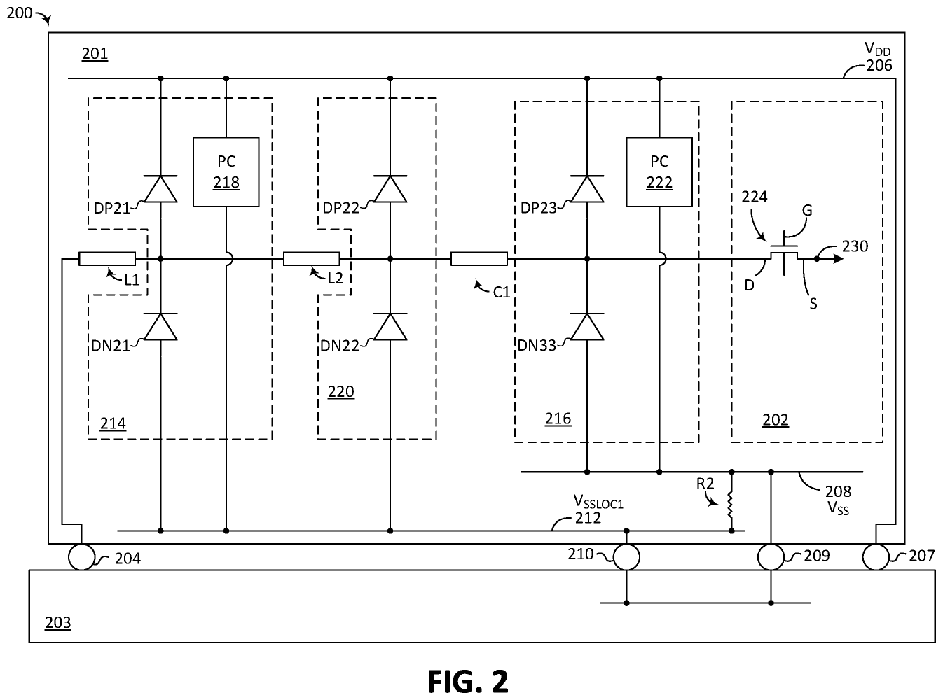

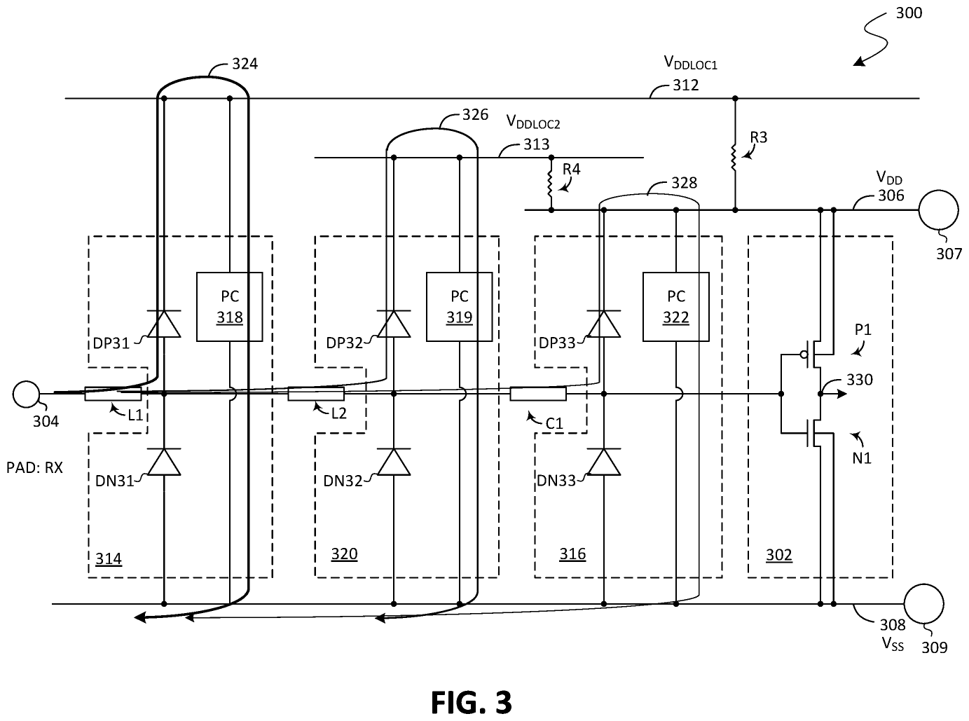

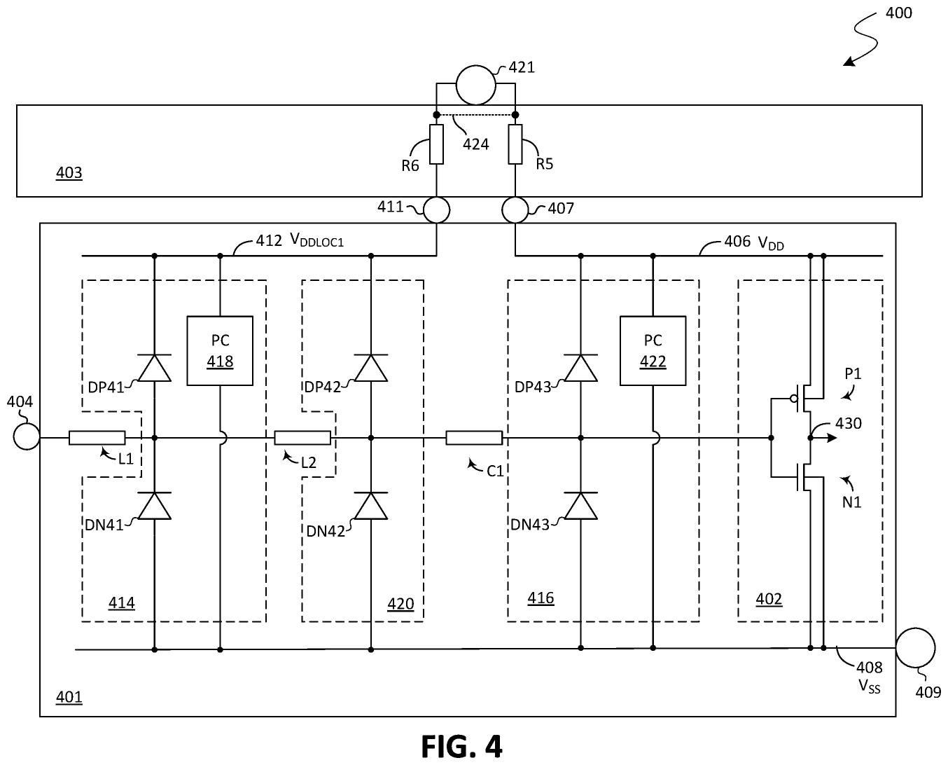

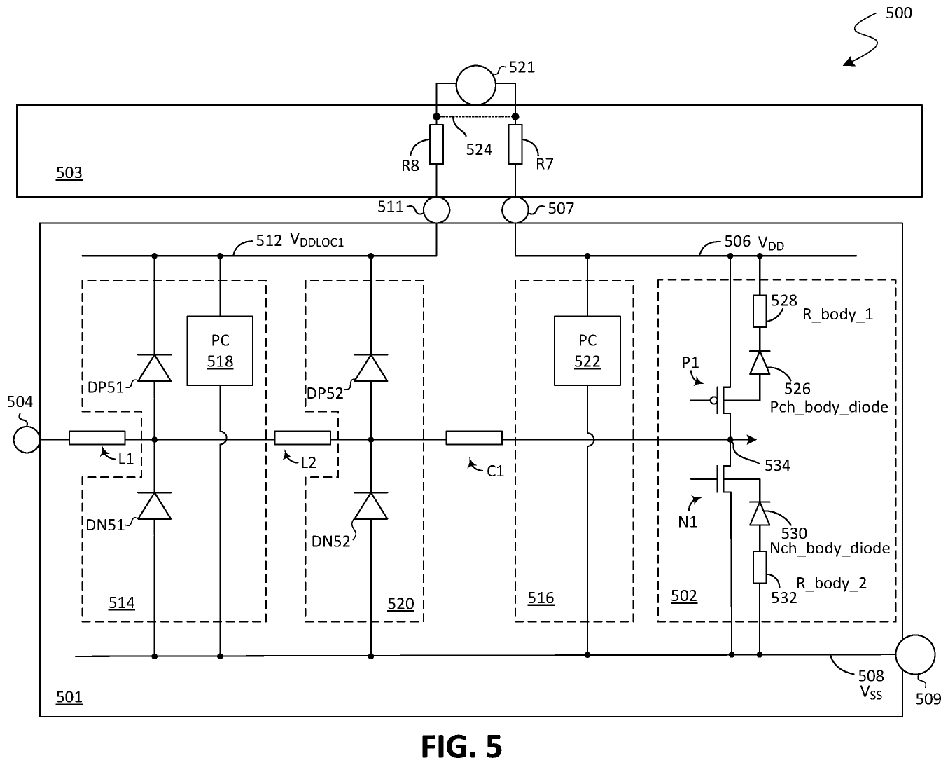

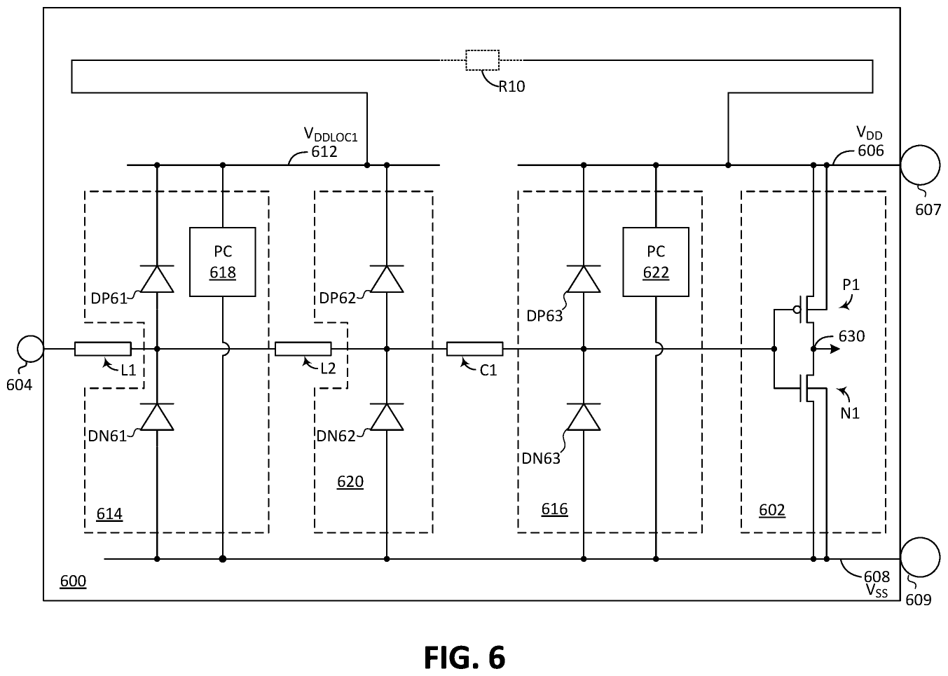

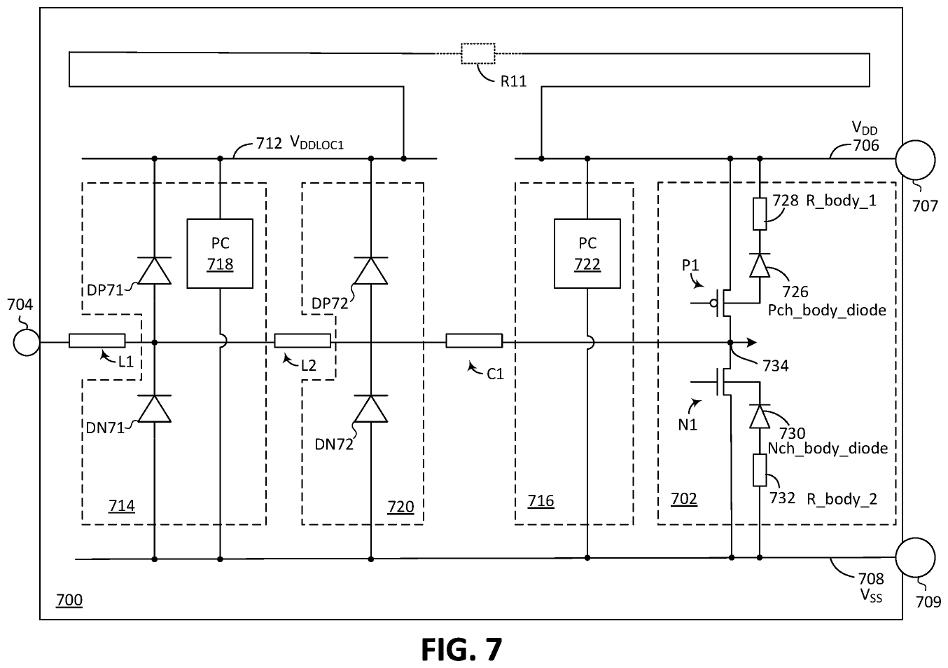

Power clamps are known in the art and the power clamps referred to herein may be any suitable known power clamp. In embodiments, PC 118 and PC 122 of FIG. 1; PC 218 and PC 222 of FIG. 2; PC 318, PC 319, and PC 322 of FIG. 3; PC 418 and PC 422 of FIG. 4; PC 418 and PC 422 of FIGS. 4 and 5; PC 618 and PC 622 of FIG. 6; and PC 718 and PC 722 of FIG. 7 comprise a resistor-capacitor (RC) MOS FET based switching structure. In some embodiments, any of these power clamps comprise a thyristor. In some embodiments, any of these power clamps comprise a capacitor with a large capacitance value. In some embodiments, any of these power clamps comprise one or more BJT devices. In some embodiments, any of these power clamps comprise one or more diodes. In some embodiments, any of the power clamps referred to herein comprise a combination of two or more of a RC MOS FET based switching structure, a thyristor, a capacitor, a BJT, and a diode.

In some embodiments, second stage ESD protection circuitry 120 may be provided. In the example shown in FIG. 1, second stage ESD protection circuitry 120 comprises a diode DP2 and a diode DN2. Diode DP2 is coupled between the conductive contact 104 and the third supply line 112 (V_{DDLOC1}). Diode DN2 is coupled between the conductive contact 104 and the second ground reference line 108 (V_{SS}). Diodes DP2 and DN2 are coupled with conductive contact 104 via component L2. In various, embodiments the component L2 may be an inductor, a capacitor, or a resistor. The diode DP2 may be p-type diode and the diode DN2 may be n-type diode. The cathode of the diode DP2 is coupled with the third supply line 112 while the anode of is coupled with conductive contact 104. The cathode of the diode DN2 is coupled with the conductive contact 104 while the anode of is coupled with ground reference line 108. The respective sizes of diode DP2 and diode DN2 may be smaller than that of diode DP1 and diode DN1.

In some embodiments, IC device 100 comprises third ESD protection circuitry 116. The third ESD protection circuitry 116 may include a variety of different components in different embodiments. As illustrated in FIG. 1, third ESD protection circuitry 116 comprises diode DP3, diode DN3, and PC 122. Diode DP3 is coupled between the first conductive contact 104 and the first supply line (V_{DD}) 106. Diode DN3 is coupled between the first conductive contact 104 and second supply line (V_{SS}) 108. Diodes DP3 and DN3 may be coupled with conductive contact 104 via component C1 as shown in the figure. Diodes DP3 and DN3 may also be coupled with conductive contact 104 via components L1 and L2. The diode DP3 may be a p-type type diode and the diode DN3 may be an n-type type diode. The cathode of the diode DP3 is coupled with the first supply line 106 while the anode of is coupled with first conductive contact 104. The cathode of diode DN3 is coupled with first conductive contact 104 while the anode of is coupled with the second supply line 108. In various embodiments, the component C1 may be an inductor, a capacitor, or a resistor. In some embodiments, the component C1 is a resistor coupling first circuitry 102 with conductive contact 104, which comprises a variable resistance that increases in response to an ESD event as described elsewhere herein.

In some embodiments, third ESD protection circuitry 116 includes power clamp PC 122 coupled between the first supply line 106 and the second supply line 108. PC 122 may include a variety of different components in different embodiments. PC 122 may comprise any power clamp component described herein.

As mentioned, first circuitry 102 may be any circuitry or structure to be protected from an ESD event. First circuitry 102 may take variety of different circuit arrangements and components in different embodiments. In the example of FIG. 1, first circuitry 102 comprises an inverter. In an embodiment, first circuitry 102 comprises a first transistor of a first conductivity type and a second transistor of a second conductivity type. The first and second conductivity types are different from one another. First circuitry 102 includes a p-type transistor P1 and an n-type transistor N1. First transistor P1 is coupled with the conductive contact 104 (at its gate terminal). Second transistor N1 is coupled with the conductive contact 104 (at its drain terminal). The first transistor P1 and the second transistor N1 are coupled in series with each other (at their drain terminals) at node 130 between the first supply line 106 and the second supply line 108. In addition, in the example of FIG. 1, a body of the first transistor P1 is coupled with the first supply line 106 and a body of the second transistor is coupled with the second supply line. The node 130 where first transistor P1 and the second transistor N1 are coupled may be coupled to any desired and suitable circuitry (not shown) within the IC device 100. If first circuitry 102 is coupled with a receiver, the gate terminals of P1 and N1 are coupled with the conductive contact, as shown in the figure. If first circuitry 102 is coupled with a transmitter, the drain terminals of P1 and N1 are coupled with conductive contact 104. For example, the node 130 may be coupled with a SERDES.

ESD discharge current paths for a negative CDM stress are indicated by arrows 124, 126 and 128. A primary ESD discharge current 124 flows through diode DP1 and power clamp PC 118. A secondary ESD discharge current 126 flows through diode DP2 and power clamp PC 118. A residual ESD discharge current 128 flows through diode DP3 and power clamp PC 122. The primary ESD current is larger than the secondary ESD current, while the residual ESD current is smaller than the secondary ESD current.

FIG. 2 is a schematic diagram of an IC device comprising interface circuitry and ESD protection circuitry employing first, second, and third supply lines, in accordance with some embodiments. IC package 200 comprises two or more IC devices, e.g., two or more tiles, chips, chiplets, or dies. In the example of FIG. 2, IC package 200 comprises IC device 201 and a component 203. Component 203 may be a package substrate, an IC die, or another component. As illustrated in FIG. 2, IC device 201 comprises first circuitry 202 coupled with a first conductive contact 204. First circuitry 202 may be a victim or target to be protected by ESD protection circuitry. First circuitry 202 may be any circuitry or structure to be protected from an ESD event. In various embodiments, first circuitry 202 is an inverter, a HF switch, an input to a HISO receiver, or an input to an LNA. First circuitry 202 may comprise a serial interface. The first supply line 206 is coupled to provide a supply voltage V_{DD} and the second supply line 208 is coupled to provide a ground reference voltage V_{SS}. The second supply line 208 may also be referred to herein as a ground reference voltage line. The first supply line 206 may be coupled with a second conductive contact 207 and the second supply line 208 may be coupled with a third conductive contact 209. In some embodiments, the first conductive contact 204 may be an I/O pad, the second conductive contact 207 may be a power supply pad (V_{DD}), and the third conductive contact 209 may be a ground reference voltage (V_{SS}) pad. In embodiments, first conductive contact 204 is an I/O pad for receiving a signal or transmitting a signal.

A resistive element R2 is coupled between the second supply line 208 and a third supply line 212. The third supply line 212 may be referred to herein as a local ground reference voltage V_{SSLOC1} line. In some embodiments, the resistive element R2 comprises one or more metal conductive paths or traces in one or more metallization layers of the IC device 201. In some embodiments, the resistive element R2 comprises a polycrystalline silicon material. In embodiments, the resistive element R2 has a resistance value of at least 500 ohms. In some embodiments, the only coupling between second supply line and the third supply line is the resistive element R2. The third supply line 212 may be may be coupled with a fourth conductive contact 210, which may be a ground reference voltage (V_{SSLOC1}) pad. Fourth conductive contact 210 may electrically connect IC package 200 with component 203. As shown in FIG. 2, in some embodiments, the ground reference voltage (V_{SS}) and local ground reference voltage (V_{SSLOC1}) may be coupled with each other within component 203.

In the example of FIG. 2, first ESD protection circuitry 214 is coupled with the first conductive contact 204. First ESD protection circuitry 214 is also coupled between the third supply line 212 (V_{SSLOC1}) and the first supply line 206 (V_{DD}). The first ESD protection circuitry 214 may include a variety of different components in different embodiments. In the example shown in FIG. 2, first ESD protection circuitry 214 includes a diode DP21 coupled between the first conductive contact 204 and the first supply line 206, and a diode DN21 coupled between the first conductive contact 204 and the third supply line 212. The diode DP21 may be a p-type type diode and the diode DN21 may be an n-type type diode. The cathode of the diode DP21 is coupled with the first supply line 206 while the anode of is coupled with first conductive contact 204. The cathode of the diode DN21 is coupled with first conductive contact 204 while the anode of is coupled with the third supply line 212. First ESD protection circuitry 214 may be coupled with the conductive contact 204 by component L1. In various, embodiments, the component L1 may be an inductor, a capacitor, or a resistor.

In some embodiments, the first ESD protection circuitry 214 includes a power clamp PC 218 coupled between the third supply line 212 and the first supply line 206. PC 218 may include a variety of different components in different embodiments. PC 218 may comprise any power clamp component described herein.

In some embodiments, second stage ESD protection circuitry 220 may be provided. In the example shown in FIG. 2, second stage ESD protection circuitry 220 comprises a diode DP22 and a diode DN22. Diode DP22 is coupled between the conductive contact 204 and the first supply line 206. Diode DN22 coupled between the conductive contact 204 and the third supply line 212. Diodes DP22 and DN22 are coupled with conductive contact 104 via component L2. In various, embodiments, the component L2 may be an inductor, a capacitor, or a resistor. The diode DP22 may be p-type diode and the diode DN22 may be n-type diode. The cathode of the diode DP22 is coupled with the first supply line 206 while the anode of is coupled with conductive contact 204. The cathode of the diode DN22 is coupled with the conductive contact 204 while the anode of is coupled with the third supply line 212. The respective sizes of diode DP22 and diode DN22 may be smaller than that of diode DP21 and diode DN21.

In some embodiments, IC device 201 comprises third ESD protection circuitry 216. The third ESD protection circuitry 216 may include a variety of different components in different embodiments. The third ESD protection circuitry 216 may be coupled between first supply line (V_{DD}) 206 and second supply line (V_{SS}) 208. In the example of FIG. 2, third ESD protection circuitry 216 comprises diode DP23, diode DN23, and PC 222. Diode DP23 is coupled with the conductive contact 204 and the first supply line (V_{DD}) 206. Diode DN23 is coupled between the first conductive contact 104 and second supply line (V_{SS}) 208. Diodes DP23 and DN23 may be coupled with conductive contact 204 via component C1 as shown in the figure. Diodes DP23 and DN23 may also be coupled with conductive contact 204 via components L1 and L2. The diode DP3 may be a p-type type diode and the diode DN3 may be an n-type type diode. The cathode of the diode DP3 is coupled with the first supply line 206 while the anode of is coupled with first conductive contact 204. The cathode of diode DN3 is coupled with first conductive contact 204 while the anode of is coupled with the second supply line 208. In various, embodiments, the component C1 may be an inductor, a capacitor, or a resistor. In some embodiments, the component C1 is a resistor coupling first circuitry 202 with conductive contact 204, which comprises a variable resistance that increases in response to an ESD event as described elsewhere herein.

In some embodiments, third ESD protection circuitry 216 includes a power clamp PC 222 coupled between the first supply line 206 and the second supply line 208. PC 222 may include a variety of different components in different embodiments. PC 222 may comprise any power clamp component described herein.

As mentioned, first circuitry 202 may be any circuitry or structure to be protected from an ESD event. First circuitry 202 may take a variety of different circuit arrangements and components in different embodiments. In the example illustrated in FIG. 2, first circuitry 202 comprises a HF switch. In an embodiment, first circuitry 202 comprises transistor 224, which may be a metal oxide semiconductor field effect transistor (MOSFET). Transistor 224 may be a planar or fin-type FET (finFET). Transistor 224 may be an n-type or a p-type transistor. A drain terminal D is coupled with the first conductive contact 204, either directly, or via one or more components. In an embodiment, drain terminal D is coupled with the first conductive contact 204 via components L1, L2, and C1. A source terminal S is coupled with node 230, which may be coupled with any desired and suitable circuitry (not shown) within the IC device 201. For example, the node 230 may be coupled with a SERDES. In some embodiments, the gate G of transistor 224 is coupled with pre-driver circuitry (not shown in the figure). The gate G may be coupled directly or via a resistor. In some embodiments, the body of transistor 224 is coupled with a reference voltage (not shown in the figure), either directly or via a resistor. In some embodiments, first circuitry 202 comprises a HF switch that comprises two or more transistors.

FIG. 3 is a schematic diagram of an IC device comprising interface circuitry and ESD protection circuitry employing first, second, third, and fourth supply lines, in accordance with some embodiments. IC device 300 comprises first circuitry 302 coupled with a first conductive contact 304. First circuitry 302 is also coupled between a first supply line 306 and a second supply line 308. First circuitry 302 may be a victim or target to be protected by ESD protection circuitry. First circuitry 302 may be any circuitry or structure to be protected from an ESD event. In various embodiments, first circuitry 302 is an inverter, a HF switch, an input to a HISO receiver, or an input to an LNA. First circuitry 302 may comprise a serial interface. The first supply line 306 is coupled to provide a supply voltage (V_{DD}) and the second supply line 308 is coupled to provide a ground reference voltage (V_{SS}). The second supply line 308 may also be referred to herein as a ground reference voltage line. In some embodiments, the first supply line 306 is coupled with a second conductive contact 307 and the second supply line 308 is coupled with a third conductive contact 309. In some embodiments, the first conductive contact 304 may be an I/O pad, the second conductive contact 307 may be a power supply pad (V_{DD}), and the third conductive contact 309 may be a ground reference voltage (V_{SS}) pad. In embodiments, first conductive contact 304 is an I/O pad for receiving a signal or transmitting a signal.

A resistive element R3 is coupled between the first supply line 306 and a third supply line 312. The third supply line 312 is referred to herein as a “local” supply voltage V_{DDLOC1}. In contrast to the example of FIG. 1, IC device 300 includes a second resistive element R4 coupled between the first supply line 306 and a fourth supply line 313. The fourth supply line 313 is referred to herein as a local supply voltage V_{DDLOC2}. It should be appreciated that the number of local supply lines is not limited to two, e.g., V_{DDLOC1} and V_{DDLOC2}. In various embodiments, more than two local supply lines may be provided. In these embodiments, each local supply line is decoupled from first supply line 306 (V_{DD}) by one or more resistive elements.

In some embodiments, the resistive elements R3 and R4 each comprise one or more metal conductive paths or traces in one or more metallization layers of the IC device 300. In some embodiments, the resistive elements R3 and R4 comprise a polycrystalline silicon material. In embodiments, the resistive elements R3 and R4 each have a resistance value of at least 500 ohms. In some embodiments, the only coupling between first supply line and the third supply line is the resistive element R3. In some embodiments, the only coupling between first supply line and the fourth supply line is the resistive element R4.

As illustrated in FIG. 3, first ESD protection circuitry 314 is coupled with the first conductive contact 304. First ESD protection circuitry 314 is also coupled between the third supply line 312 (V_{DDLOC1}) and the second supply line 308 (V_{SS}). The first ESD protection circuitry 314 may include a variety of different components in different embodiments. In the example shown in FIG. 3, first ESD protection circuitry 314 includes a diode DP31 coupled between the first conductive contact 304 and the third supply line 312, and a diode DN31 coupled between the first conductive contact 304 and the second supply line 308. The diode DP31 may be a p-type type diode and the diode DN31 may be an n-type type diode. The cathode of the diode DP31 is coupled with the third supply line 312 while the anode of is coupled with first conductive contact 304. The cathode of the diode DN31 is coupled with first conductive contact 304 while the anode of is coupled with the second supply line 308. First ESD protection circuitry 314 may be coupled with the conductive contact 304 by component L1. In various, embodiments, the component L1 may be an inductor, a capacitor, or a resistor.

In some embodiments, the first ESD protection circuitry 314 includes a power clamp PC 318 coupled between the third supply line 312 and the second supply line 308. PC 318 may include a variety of different components in different embodiments. PC 318 may comprise any power clamp component described herein.

As illustrated in FIG. 3, second stage ESD protection circuitry 320 may be provided. In the example shown in FIG. 3, second stage ESD protection circuitry 320 comprises a diode DP32 and a diode DN32. Diode DP32 is coupled between the conductive contact 304 and the fourth supply line 313. Diode DN32 is coupled between the conductive contact 304 and the second supply line 308. Diodes DP32 and DN32 are coupled with conductive contact 304 via components L1 and L2. In various, embodiments the component L2 may be an inductor, a capacitor, or a resistor. The diode DP32 may be p-type diode and the diode DN32 may be n-type diode. The cathode of the diode DP32 is coupled with the fourth supply line 313 while the anode of is coupled with conductive contact 304. The cathode of the diode DN32 is coupled with the conductive contact 304 while the anode of is coupled with the second supply line 308. The respective sizes of diode DP32 and diode DN32 may be smaller than that of diode DP31 and diode DN31.

In some embodiments, the second stage ESD protection circuitry 320 includes a PC 319 coupled between the fourth supply line 313 and the second supply line 308. PC 319 may include a variety of different components in different embodiments. PC 319 may comprise any power clamp component described herein.

In some embodiments, IC device 300 comprises third ESD protection circuitry 316. The third ESD protection circuitry 316 may include a variety of different components in different embodiments. As illustrated in FIG. 3, third ESD protection circuitry 316 comprises diode DP33, diode DN33, and PC 322. Diode DP33 is coupled between the first conductive contact 304 and the first supply line (V_{DD}) 306. Diode DN33 is coupled between the first conductive contact 304 the second supply line (V_{SS}) 308. Diodes DP33 and DN33 may be coupled with first conductive contact 304 via components C1, L1, and L2 as shown in the figure. The diode DP33 may be a p-type type diode and the diode DN33 may be an n-type type diode. The cathode of the diode DP33 is coupled with the first supply line 306 while the anode is coupled with first conductive contact 304. The cathode of diode DN33 is coupled with first conductive contact 304 while the anode of is coupled with the second supply line 308. In various, embodiments, the component C1 may be an inductor, a capacitor, or a resistor. In some embodiments, the component C1 is a resistor coupling first circuitry 302 with conductive contact 304, which comprises a variable resistance that increases in response to an ESD event as described elsewhere herein. As mentioned, each of components L1 and L2 may be an inductor, a capacitor, or a resistor.

In some embodiments, third ESD protection circuitry 316 includes a power clamp PC 322 coupled between the first supply line 306 and the second supply line 308. PC 322 may include a variety of different components in different embodiments. PC 322 may comprise any power clamp component described herein.

As mentioned, first circuitry 302 may be a HF switch. First circuitry 302 may take variety of different circuit arrangements and components in different embodiments. In the example illustrated in FIG. 3, first circuitry 302 comprises a first transistor of a first conductivity type and a second transistor of a second conductivity type. The first and second conductivity types are different from one another. In the example of FIG. 3, first circuitry 302 comprises a two-transistor inverter. First circuitry 302 includes a p-type transistor P1 and an n-type transistor N1. First transistor P1 is coupled with the conductive contact 304 (at its gate terminal). Second transistor N1 is coupled with the conductive contact 304 (at its gate terminal). In some embodiments, transistors P1 and N1 can be stacked with additional p- and n-type devices. The first transistor P1 and the second transistor N1 are coupled in series with each other (at their drain terminals) at node 330 between the first supply line 306 and the second supply line 308. In addition, in the example of FIG. 3, a body of the first transistor P1 is directly connected with the first supply line 306 and a body of the second transistor is directly connected with the second supply line 308. In other embodiments, the body of P1 may be coupled with the first supply line 306 via a structure (an inductor, a capacitor, a resistor, or any combination thereof). In other embodiments, the body of N1 may be coupled with the second supply line 308 via a structure (an inductor, a capacitor, a resistor, or any combination thereof). The node 330 where first transistor P1 and the second transistor N1 are coupled may be coupled to any desired and suitable circuitry (not shown) within the IC device 300. If first circuitry 302 is coupled with a receiver, the gate terminals of P1 and N1 are coupled with the conductive contact 304 via L1, L2, and C1, as shown in the figure. If first circuitry 302 is coupled with a transmitter, the drain terminals of P1 and N1 are coupled with conductive contact 304. For example, the node 330 may be coupled with a SERDES. In various embodiments, any suitable circuit may be employed as first circuitry 302.

ESD discharge current paths for a negative CDM stress, in an exemplary “worst case” scenario, are indicated by arrows 324, 326 and 328. A primary ESD discharge current 324 flows through diode DP31 and power clamp PC 318. A secondary ESD discharge current 326 flows through diode DP32 and power clamp PC 319. A residual ESD discharge current 328 flows through diode DP33 and power clamp PC 322. As indicated by the thickness of the arrows, preferably, the primary ESD current may be larger than the secondary ESD current, while the residual ESD current may be smaller than the secondary ESD current.

The IC device 201 shown in FIG. 2 is similar to integrated circuit device 100 shown in FIG. 1, except that the third supply line is coupled to ground reference V_{SS}. In a like manner, in an alternative embodiment, IC device 300 can be arranged so that both the third (local) supply line 312 and the fourth supply (local) line 313 are coupled via respective resistors R3 and R4 to second supply (ground reference) line 308 (V_{SS}). In contrast to the example of FIG. 3, in this alternative IC device, the third (local) supply line 312 may be a local ground reference voltage (V_{SSLOC1}) and fourth (local) supply line 313 may be a local reference voltage (V_{SSLOC2}). In the alternative embodiment, first ESD protection circuitry 314 is coupled with the first conductive contact 304 and between the third ground reference line (V_{SSLOC1}) and the first supply line 306 (V_{DD}). Similarly, second stage ESD protection circuitry 320 is coupled with the first conductive contact 304 and between the fourth ground reference line (V_{SSLOC2}) and the first supply line 306. In the same manner as IC 300, third ESD protection circuitry 316 is coupled with first conductive contact 304 and between first supply line (V_{DD}) 306 and second supply line (V_{SS}) 308 in the alternative embodiment. It should be appreciated that the number of local ground reference lines is not limited to two, e.g., V_{SSLOC1} and V_{SSLOC2}. In various embodiments, more than two local ground reference may be provided. In these embodiments, each local ground reference line is decoupled from second (ground reference) supply line 306 (V_{SS}) by one or more resistive elements. Moreover, in some embodiments, two or more local supply lines and two or more local ground reference lines may be provided.

FIG. 4 is a schematic diagram of an IC package comprising interface circuitry and ESD protection circuitry employing first, second, and third supply lines, in accordance with some embodiments. IC package 400 comprises two or more IC devices, e.g., two or more tiles, chips, chiplets, or dies. In the example of FIG. 4, IC package 400 comprises IC device 401 and a component 403. Component 403 may be a package substrate, an IC die, or another component. As illustrated in FIG. 4, IC device 401 comprises first circuitry 402, first conductive contact 404, first supply line 406, second supply line 408, and third supply line 412. First circuitry 402 may be a victim or target to be protected by ESD protection circuitry. First circuitry 402 may be any circuitry or structure to be protected from an ESD event. In various embodiments, first circuitry 402 is an inverter, a HF switch, an input to a HISO receiver, or an input to an LNA. First circuitry 402 may comprise a serial interface. IC device 401 also includes first ESD protection circuitry 414, second stage ESD protection circuitry 420, and third ESD protection circuitry 416. In addition, IC device 401 includes second conductive contact 407, the third conductive contact 409, and fourth conductive contact 411. In embodiments, first conductive contact 404 is an I/O pad for receiving a signal or transmitting a signal. In some embodiments, the second conductive contact 407 may be a power supply pad (V_{DD}), the third conductive contact 409 may be a ground reference voltage (V_{SS}) pad, and fourth conductive contact 411 may be a power supply pad (V_{DDLOC1}).

Referring back to FIG. 1, resistive element R1 in IC device 100 couples the first supply line 106 and third supply line 112. Resistive element R1 is used to decouple first ESD protection circuitry 114 from first circuitry 102. In contrast, in IC device 401, resistive elements R5 and R6 are used to decouple first ESD protection circuitry 414 from first circuitry 402 are provided in component 403. Resistive elements R5 and R6 may be in component 403 or in another component of the IC package 400. In embodiments, the resistive element used to decouple first ESD protection circuitry 414 from first circuitry 402 are provided externally to IC device 401. In some embodiments, the only coupling between first supply line and the third supply line are the resistive elements R5 and/or R6.

Except for the location of a decoupling resistive element, IC device 401 comprises elements that are the same as or similar to elements of IC device 100. First ESD protection circuitry 414 may be the same as or similar to first ESD protection circuitry 114. The first ESD protection circuitry 414 is coupled with the first conductive contact 404 and between the third supply line 412 (V_{DDLOC1}) and the second supply line 408 (V_{SS}). The second supply line 408 may also be referred to herein as a ground reference voltage line. First ESD protection circuitry 414 includes a diode DP41 coupled between the first conductive contact 404 and the third supply line 412, and a diode DN41 coupled between the first conductive contact 404 and the second supply line 408. The diode DP41 may be a p-type type diode and the diode DN41 may be an n-type type diode. First ESD protection circuitry 414 may be coupled with the conductive contact 404 by component L1. In various, embodiments, the component L1 may be an inductor, a capacitor, or a resistor.

In some embodiments, first ESD protection circuitry 414 includes a power clamp PC 418 coupled between the third supply line 412 and the second supply line 408. PC 418 may include a variety of different components in different embodiments. PC 418 may comprise any power clamp component described herein.

Second ESD protection circuitry 420 may be the same as or similar to second stage ESD protection circuitry 120. The second stage ESD protection circuitry 420 is coupled with the first conductive contact 404 and between the third supply line 412 (V_{DDLOC1}) and the second supply line 408 (V_{SS}). Second ESD protection circuitry 420 includes a diode DP42 coupled between the first conductive contact 404 and the third supply line 412, and a diode DN42 coupled between the first conductive contact 404 and second supply line 408. The diode DP42 may be a p-type type diode and the diode DN42 may be an n-type type diode. Second ESD protection circuitry 420 may be coupled with the conductive contact 404 by component L2. In various, embodiments, the component L2 may be an inductor, a capacitor, or a resistor.

Third ESD protection circuitry 416 may be the same as or similar to third ESD protection circuitry 116. Third ESD protection circuitry 416 is coupled with first conductive contact 404 and between first supply line 406 (V_{DD}) and second supply line 408 (V_{SS}). Third ESD protection circuitry 416 comprises diode DP43, diode DN43, and PC 422. Diode DP43 is coupled between the first conductive contact 404 and the first supply line (V_{DD}) 406. Diode DN43 is coupled between the first conductive contact 404 and second supply line (V_{SS}) 408. Diodes DP43 and DN43 may be coupled with conductive contact 404 via component C1 as shown in the figure. Diodes DP43 and DN43 may also be coupled with conductive contact 404 via components L1 and L2. The diode DP43 may be a p-type type diode and the diode DN43 may be an n-type type diode. In various embodiments, the component C1 may be an inductor, a capacitor, or a resistor. In an embodiment, component C1 is a capacitor having a 1 pF value.

In some embodiments, third ESD protection circuitry 416 includes power clamp PC 422 coupled between the first supply line 406 and the second supply line 408. PC 422 may include a variety of different components in different embodiments. PC 422 may comprise any power clamp component described herein.

First circuitry 402 may be the same as or similar to first circuitry 102. First circuitry 402 may be a HF switch. First circuitry 402 may take variety of different circuit arrangements and components in different embodiments. In the example illustrated in FIG. 4, first circuitry 402 comprises a first transistor of a first conductivity type and a second transistor of a second conductivity type. The first and second conductivity types are different from one another. In an embodiment, first circuitry 402 comprises an inverter. First circuitry 402 includes a p-type transistor P1 and an n-type transistor N1. First transistor P1 is coupled with the conductive contact 404 (at its gate terminal). Second transistor N1 is coupled with the conductive contact 404 (at its drain terminal). The first transistor P1 and the second transistor N1 are coupled in series with each other (at their drain terminals) at node 430 between the first supply line 406 and the second supply line 408. In addition, a body of the first transistor P1 is coupled with the first supply line 406 and a body of the second transistor is coupled with the second supply line 408. The node 430 where first transistor P1 and the second transistor N1 are coupled may be an output node that may be coupled to any desired and suitable circuitry (not shown) within the IC device 401. If first circuitry 402 is coupled with a receiver, the gate terminals of P1 and N1 are coupled with the conductive contact 404, as shown in the figure. If first circuitry 402 is coupled with a transmitter, the drain terminals of P1 and N1 are coupled with conductive contact 404. For example, the node 430 may be coupled with a SERDES. In various embodiments, any suitable circuit may be employed as first circuitry 402.

As illustrated in FIG. 4, first supply line 406 is coupled with a second conductive contact 407, second supply line 408 is coupled with a third conductive contact 409, and third supply line 412 is coupled with a fourth conductive contact 411. The second conductive contact 407 and fourth conductive contact 411 are coupled with interconnects of component 403. Second contact 407 and fourth contact 411 may be soldered or bonded to pads on component 403. Alternatively, second contact 407 and fourth contact 411 may be directly bonded to interconnect structures of component 403, e.g., covalently bonded after subsequent temperature processing of the microelectronic package structure. In direct bonding embodiments, respective dielectrics of dielectric layers of the IC die 401 and component 403 are also directly bonded to each other.

In an embodiment, component 403 comprises a fifth conductive contact 421. Second conductive contact 407 may be coupled, directly or via a resistor, with the fifth conductive contact 421 in some embodiments. Fourth conductive contact 411 may be coupled, directly or via a resistor, with the fifth conductive contact 421 in some embodiments.

In some embodiments, one or more resistive elements external to IC device 401 are provided between first supply line 406 and third supply line 412. The resistive elements external to IC device 401 can comprise a parasitic resistance or inductance that results from the interconnect structures between IC device 401 and component 403. In some embodiments, second conductive contact 407 and fourth conductive contact 411 may be coupled with fifth conductive contact 421 via resistive elements R5 and R6, as shown in FIG. 4. In some embodiments, second conductive contact 407 and fourth conductive contact 411 may be coupled with fifth conductive contact 421 via only one of resistive elements R5 and R6, i.e., one resistive element may be omitted. In some embodiments, second conductive contact 407 and fourth conductive contact 411 may be coupled together via a conductive pathway or material 424 within component 403.

FIG. 5 is a schematic diagram of an IC package comprising interface circuitry and ESD protection circuitry employing first, second, and third supply lines, in accordance with some embodiments. IC package 500 comprises two or more IC devices, e.g., two or more tiles, chips, chiplets, or dies. In the example of FIG. 5, IC package 500 comprises IC device 501 and a component 503. Component 503 may be a package substrate, and IC die, or another component. As illustrated in FIG. 5, IC device 501 comprises first circuitry 502, first conductive contact 504, first supply line 506, second supply line 508, and third supply line 512. First circuitry 502 may be a victim or target to be protected by ESD protection circuitry. First circuitry 502 may be any circuitry or structure to be protected from an ESD event. In various embodiments, first circuitry 502 is an inverter, a HF switch, an input to a HISO receiver, or an input to an LNA. First circuitry 502 may comprise a serial interface. IC device 501 also includes first ESD protection circuitry 514, second stage ESD protection circuitry 520, and third ESD protection circuitry 516. In addition, IC device 501 includes second conductive contact 507, the third conductive contact 509, and fourth conductive contact 511. In embodiments, first conductive contact 504 is an I/O pad for receiving a signal or transmitting a signal. In some embodiments, the second conductive contact 507 may be a power supply pad (V_{DD}), the third conductive contact 509 may be a ground reference voltage (V_{SS}) pad, and fourth conductive contact 511 may be a power supply pad (V_{DDLOC1}).

Referring back to FIG. 1, resistive element R1 in IC device 100 couples the first supply line 106 and third supply line 112. Resistive element R1 is used to decouple first ESD protection circuitry 114 from first circuitry 102. In contrast, in IC device 501, resistive elements R7 and R8 are used to decouple first ESD protection circuitry 514 from first circuitry 502 are provided in component 503. Resistive elements R7 and R8 may be in component 503 or another component of the IC package 500. In embodiments, the resistive element used to decouple first ESD protection circuitry 514 from first circuitry 502 are provided externally to IC device 501. In some embodiments, the only coupling between first supply line and the third supply line are the resistive elements R7 and/or R8.

Referring again to FIG. 1, IC device 100 comprises third ESD protection circuitry 116. In the example shown in FIG. 1, third ESD protection circuitry 116 comprises diode DP3, diode DN3, and PC 122. In contrast, third ESD protection circuitry 516 of IC device 501 may not include diodes similar to DP3 and DN3. Instead, third ESD protection circuitry 516 employs parasitic diodes and resistances of transistors P1 and N1. Specifically, p-channel diode (Pch_body_diode) 526 and resistance (R_body_1) 528 are provided in place of DP3. Further, n-channel diode (Nch_body_diode) 530 and resistance (R_body_2) 532 are provided in place of DN3. The p- and n-channel diodes and associated resistances are provided within first circuitry 502, rather than third ESD protection circuitry 516. In some embodiments, third ESD protection circuitry 516 comprises PC 522.

Except for the location of a decoupling resistive element and third ESD protection circuitry 516, IC device 501 comprises elements that are the same as or similar to elements of IC device 100. First ESD protection circuitry 514 may be the same as or similar to first ESD protection circuitry 114. The first ESD protection circuitry 514 is coupled with the first conductive contact 504 and between the third supply line 512 (V_{DDLOC1}) and the second supply line 508 (V_{SS}). The second supply line 508 may also be referred to herein as a ground reference voltage line. First ESD protection circuitry 514 includes a diode DP51 coupled between the first conductive contact 504 and the third supply line 512, and a diode DN51 coupled between the first conductive contact 504 and the second supply line 508. The diode DP51 may be a p-type type diode and the diode DN51 may be an n-type type diode. First ESD protection circuitry 514 may be coupled with the conductive contact 504 by component L1. In various, embodiments, the component L1 may be an inductor, a capacitor, or a resistor.

In some embodiments, first ESD protection circuitry 514 includes a power clamp PC 518 coupled between the third supply line 512 and the second supply line 508. PC 518 may include a variety of different components in different embodiments. PC 518 may comprise any power clamp component described herein.

Second ESD protection circuitry 520 may be the same as or similar to second stage ESD protection circuitry 120. The second stage ESD protection circuitry 520 is coupled with the first conductive contact 504 and between the third supply line 512 (V_{DDLOC1}) and the second supply line 508 (V_{SS}). Second ESD protection circuitry 520 includes a diode DP52 coupled between the first conductive contact 504 and the third supply line 512, and a diode DN52 coupled between the first conductive contact 504 and second supply line 508. The diode DP52 may be a p-type type diode and the diode DN52 may be an n-type type diode. Second ESD protection circuitry 520 may be coupled with the conductive contact 504 by component L2. In various, embodiments, the component L2 may be an inductor, a capacitor, or a resistor.

In some embodiments, third ESD protection circuitry 516 includes power clamp PC 522 coupled between the first supply line 506 and the second supply line 508. PC 522 may include a variety of different components in different embodiments. PC 522 may comprise any power clamp component described herein.

First circuitry 502 may be a HF switch. First circuitry 502 may take variety of different circuit arrangements and components in different embodiments. In the example illustrated in FIG. 5, first circuitry 502 comprises a first transistor of a first conductivity type and a second transistor of a second conductivity type. The first and second conductivity types are different from one another. In an embodiment, first circuitry 502 comprises an inverter. First circuitry 502 includes a p-type transistor P1 and an n-type transistor N1. The gate terminal of first transistor P1 and the gate terminal of second transistor N1 are illustrated as floating in FIG. 5. In embodiments, the gates of P1 and N1 may be connected to any suitable circuitry for a particular application. In an embodiment, the gates of P1 and N1 are connected to pre-driver circuitry. The first transistor P1 and the second transistor N1 are coupled in series with each other (at their drain terminals) at node 534 between the first supply line 506 and the second supply line 508. A body of the first transistor P1 is coupled via p-channel diode (Pch_body_diode) 526 and resistance (R_body_1) 528 with the first supply line 506. A body of the second transistor is coupled via n-channel diode (Nch_body_diode) 530 and resistance (R_body_2) 532 with the second supply line 508. The node 534 where first transistor P1 and the second transistor N1 are coupled is coupled with conductive contact 504. In addition, node 534 may be coupled to any desired and suitable circuitry (not shown) within the IC device 501. For example, the node 534 may be coupled with a SERDES.

As illustrated in FIG. 5, first supply line 506 is coupled with a second conductive contact 507, second supply line 508 is coupled with a third conductive contact 509, and third supply line 512 is coupled with a fourth conductive contact 511. The second conductive contact 507 and fourth conductive contact 511 are coupled with interconnects of component 503. Second contact 507 and fourth contact 511 may be soldered or bonded to pads on component 503. Alternatively, second contact 507 and fourth contact 511 may be directly bonded to interconnect structures of component 503, e.g., covalently bonded after subsequent temperature processing of the microelectronic package structure. In direct bonding embodiments, respective dielectrics of dielectric layers of the IC die 501 and component 503 are also directly bonded to each other. Metal-to metal-bonding of the conductive interconnect structures (which takes place after the dielectric covalent bonding is created) is accomplished without the use of solder or underfill materials.

In an embodiment, component 503 comprises a fifth conductive contact 521. Second conductive contact 507 may be coupled with the fifth conductive contact 521 in some embodiments. Fourth conductive contact 511 may be coupled with the fifth conductive contact 521 in some embodiments.

In some embodiments, one or more resistive elements external to IC device 501 are provided between first supply line 506 and third supply line 512. The resistive elements external to IC device 501 may comprise a parasitic resistance or inductance that results from the interconnect structures between IC device 501 and component 503. In some embodiments, second conductive contact 507 and fourth conductive contact 511 may be coupled with fifth conductive contact 521 via resistive elements R5 and R6 as shown in FIG. 5. In some embodiments, second conductive contact 507 and fourth conductive contact 511 may be coupled with fifth conductive contact 521 via only one of resistive elements R5 and R6, i.e., one resistive element may be omitted. In some embodiments, second conductive contact 507 and fourth conductive contact 511 may be coupled together via a conductive pathway 524 within component 503.

FIG. 6 is a schematic diagram of an IC device comprising interface circuitry and ESD protection circuitry employing first, second, and third supply lines, in accordance with some embodiments. IC device 600 may comprise some elements that are the same as or similar to elements of IC device 100. As illustrated in FIG. 6, IC device 600 comprises first circuitry 602, first conductive contact 604, first supply line 606, second supply line 608, and third supply line 612. First circuitry 602 may be a victim or target to be protected by ESD protection circuitry. First circuitry 602 may be any circuitry or structure to be protected from an ESD event. In various embodiments, first circuitry 602 is an inverter, a HF switch, an input to a HISO receiver, or an input to an LNA. First circuitry 602 may comprise a serial interface. IC device 600 also includes first ESD protection circuitry 614, second stage ESD protection circuitry 620, and third ESD protection circuitry 616. In addition, IC device 600 includes first ESD protection circuitry 614, second stage ESD protection circuitry 620, third ESD protection circuitry 616, and element R10. In addition, IC device 600 further includes second conductive contact 607 and third conductive contact 609. In embodiments, first conductive contact 604 is an I/O pad for receiving a signal or transmitting a signal. In some embodiments, the second conductive contact 607 may be a power supply pad (V_{DD}) and third conductive contact 609 may be a ground reference voltage (V_{SS}) pad. First supply line 606 is coupled with second conductive contact 607 and second supply line 608 is coupled with third conductive contact 609.

In embodiments, IC device 600 comprises various circuitry (not shown in the figure), such as circuitry to perform logical operations, as well as circuitry to store data, e.g., registers and memory. In addition, IC device 600 comprises a plurality of conductive interconnects to deliver power to this circuitry (not shown in the figure). The plurality of conductive interconnects may be referred to herein as a “power gird.” Referring back to FIG. 1, resistive element R1 in IC device 100 couples the first supply line 106 and third supply line 112. Resistive element R1 is used to decouple first ESD protection circuitry 114 from first circuitry 102. In contrast, in IC device 600, a portion or all of the on-die power grid of IC device 600 is used to decouple first ESD protection circuitry 614 and second stage ESD protection circuitry 620 from first circuitry 602.

In FIG. 6, a portion or all of the on-die power grid of IC device 600 is represented by element R10. The element R10 represents the inherent resistance and/or inductance provided by the on-die power grid connecting first supply line 606 and third supply line 612. In some embodiments, the only coupling between first supply line and the third supply line is the resistive element R10. In embodiments, the on-die power grid may provide power to various circuitry (not shown), which may exclude circuitry 602.

First ESD protection circuitry 614 may be the same as or similar to first ESD protection circuitry 114. The first ESD protection circuitry 614 is coupled with the first conductive contact 604 and between the third supply line 612 (V_{DDLOC1}) and the second supply line 608 (V_{SS}). The second supply line 608 may also be referred to herein as a ground reference voltage line. First ESD protection circuitry 614 includes a diode DP61 coupled between the first conductive contact 604 and the third supply line 612, and a diode DN61 coupled between the first conductive contact 604 and the second supply line 608. The diode DP61 may be a p-type type diode and the diode DN61 may be an n-type type diode. First ESD protection circuitry 614 may be coupled with the conductive contact 604 by component L1. In various, embodiments, the component L1 may be an inductor, a capacitor, or a resistor. In an embodiment, first conductive contact 604 is an I/O pad for receiving a signal. In an embodiment, first conductive contact 604 is an I/O pad for transmitting a signal.

In some embodiments, first ESD protection circuitry 614 includes a power clamp PC 618 coupled between the third supply line 612 and the second supply line 608. PC 618 may include a variety of different components in different embodiments. PC 618 may comprise any power clamp component described herein.

Second ESD protection circuitry 620 may be the same as or similar to second stage ESD protection circuitry 120. The second stage ESD protection circuitry 620 is coupled with the first conductive contact 604 and between the third supply line 612 (V_{DDLOC1}) and the second supply line 608 (V_{SS}). Second ESD protection circuitry 620 includes a diode DP62 coupled between the first conductive contact 604 and the third supply line 612, and a diode DN62 coupled between the first conductive contact 604 and second supply line 608. The diode DP62 may be a p-type type diode and the diode DN62 may be an n-type type diode. Second ESD protection circuitry 620 may be coupled with the conductive contact 604 by component L2. In various, embodiments, the component L2 may be an inductor, a capacitor, or a resistor.

Third ESD protection circuitry 616 may be the same as or similar to third ESD protection circuitry 116. Third ESD protection circuitry 616 is coupled with first conductive contact 604 and between first supply line 606 (V_{DD}) and second supply line 608 (V_{SS}). Third ESD protection circuitry 616 comprises diode DP63, diode DN63, and PC 622. Diode DP63 is coupled between the first conductive contact 604 and the first supply line (V_{DD}) 606. Diode DN63 is coupled between the first conductive contact 604 and second supply line (V_{SS}) 608. Diodes DP63 and DN63 may be coupled with conductive contact 604 via component C1 as shown in the figure. Diodes DP63 and DN63 may also be coupled with conductive contact 604 via components L1 and L2. The diode DP63 may be a p-type type diode and the diode DN63 may be an n-type type diode. In various embodiments, the component C1 may be an inductor, a capacitor, or a resistor. In an embodiment, component C1 is a capacitor having a 1 pF value.

In some embodiments, third ESD protection circuitry 616 includes power clamp PC 622 coupled between the first supply line 606 and the second supply line 608. PC 622 may include a variety of different components in different embodiments. PC 622 may comprise any power clamp component described herein.

First circuitry 602 may be the same as or similar to first circuitry 102. First circuitry 602 may be a HF switch. First circuitry 602 may take variety of different circuit arrangements and components in different embodiments. In the example illustrated in FIG. 6, first circuitry 602 comprises a first transistor of a first conductivity type and a second transistor of a second conductivity type. The first and second conductivity types are different from one another. In an embodiment, first circuitry 602 comprises an inverter. First circuitry 602 includes a p-type transistor P1 and an n-type transistor N1. First transistor P1 is coupled with the conductive contact 604 (at its gate terminal). Second transistor N1 is coupled with the conductive contact 604 (at its gate terminal). In an embodiment, first circuitry 602 comprises two or more stacked n-type devices and/or two or more stacked p-type devices. First circuitry 602 may include resistors in series and/or in parallel with the n- and/or p-type devices. In an embodiment, first circuitry 602 may be a receiver. The first transistor P1 and the second transistor N1 are coupled in series with each other (at their drain terminals) at node 630 between the first supply line 606 and the second supply line 608. In addition, a body of the first transistor P1 is directly connected with the first supply line 606 and a body of the second transistor N1 is directly connected with the second supply line 608. The node where first transistor P1 and the second transistor N1 are coupled may be coupled to any desired and suitable circuitry (not shown) within the IC device 600. If first circuitry 602 is coupled with a receiver, the gate terminals of P1 and N1 are coupled with the conductive contact 604, as shown in the figure. If first circuitry 602 is coupled with a transmitter, the drain terminals of P1 and N1 are coupled with conductive contact 604. For example, the node 630 may be coupled with a SERDES. In various embodiments, any suitable circuit may be employed as first circuitry 602.

In IC device 600, the on-die power grid is used to decouple first ESD protection circuitry 614 and second stage ESD protection circuitry 620 from first circuitry 602. As mentioned, the on-die power grid of IC device 600 is represented by element R10. Element R10 is coupled between first supply line 606 and third supply line 612. In one example, the on-die power grid R10 provides a resistance of about 10 Ohms.

FIG. 7 is a schematic diagram of an IC device comprising interface circuitry and ESD protection circuitry employing first, second, and third supply lines, in accordance with some embodiments. IC device 700 comprises first circuitry 702, first conductive contact 704, first supply line 706, second supply line 708, and third supply line 712. First circuitry 702 may be a victim or target to be protected by ESD protection circuitry. First circuitry 702 may be any circuitry or structure to be protected from an ESD event. In various embodiments, first circuitry 702 is an inverter, a HF switch, an input to a HISO receiver, or an input to an LNA. First circuitry 702 may comprise a serial interface. IC device 700 also includes first ESD protection circuitry 714, second stage ESD protection circuitry 720, third ESD protection circuitry 716, and element R11. In addition, IC device 700 further includes second conductive contact 707 and third conductive contact 709. In embodiments, first conductive contact 704 is an I/O pad for receiving a signal or transmitting a signal. In some embodiments, the second conductive contact 707 may be a power supply pad (V_{DD}) and third conductive contact 709 may be a ground reference voltage (V_{SS}) pad. First supply line 706 is coupled with second conductive contact 707 and second supply line 708 is coupled with third conductive contact 709.

Referring back to FIG. 1, resistive element R1 in IC device 100 couples the first supply line 106 and third supply line 112. Resistive element R1 is used to decouple first ESD protection circuitry 114 from first circuitry 102. In contrast, in IC device 700 the on-die power grid of IC device 700 is used to decouple first ESD protection circuitry 714 and second stage ESD protection circuitry 720 from first circuitry 702. In FIG. 7, the on-die power grid of IC device 700 is represented by element R11. The element R11 represents the inherent resistance and/or inductance provided by the on-die power grid connecting first supply line 706 and third supply line 712. In some embodiments, the only coupling between first supply line and the third supply line is the resistive element R11. In embodiments, the on-die power grid may provide power to various circuitry (not shown), which may exclude circuitry 702.

Referring again to FIG. 1, IC device 100 comprises third ESD protection circuitry 116. In the example shown in FIG. 1, third ESD protection circuitry 116 comprises diode DP3, diode DN3, and PC 122. In contrast, third ESD protection circuitry 716 of IC device 701 may not include diodes similar to DP3 and DN3. Instead, third ESD protection circuitry 716 employs parasitic diodes and resistances of transistors P1 and N1. Specifically, p-channel diode (Pch_body_diode) 726 and resistance (R_body_1) 728 are provided in place of DP3. Further, n-channel diode (Nch_body_diode) 730 and resistance (R_body_2) 732 are provided in place of DN3. The p- and n-channel diodes and associated resistances are provided within first circuitry 702, rather than third ESD protection circuitry 716. In some embodiments, third ESD protection circuitry 716 comprises power clamp PC 722.

Except for the location of a decoupling resistive element and third ESD protection circuitry 716, IC device 701 comprises elements that may be the same as or similar to elements of IC device 100. First ESD protection circuitry 714 may be the same as or similar to first ESD protection circuitry 114. The first ESD protection circuitry 714 is coupled with the first conductive contact 704 and between the third supply line 712 (V_{DDLOC1}) and the second supply line 708 (V_{SS}). The second supply line 708 may also be referred to herein as a ground reference voltage line. First ESD protection circuitry 714 includes a diode DP71 coupled between the first conductive contact 704 and the third supply line 712, and a diode DN71 coupled between the first conductive contact 704 and the second supply line 708. The diode DP71 may be a p-type type diode and the diode DN71 may be an n-type type diode. First ESD protection circuitry 714 may be coupled with the conductive contact 704 by component L1. In various, embodiments, the component L1 may be an inductor, a capacitor, or a resistor.

In some embodiments, first ESD protection circuitry 714 includes a power clamp PC 718 coupled between the third supply line 712 and the second supply line 708. PC 718 may include a variety of different components in different embodiments. PC 718 may comprise any power clamp component described herein.

Second ESD protection circuitry 720 may be the same as or similar to second stage ESD protection circuitry 120. The second stage ESD protection circuitry 720 is coupled with the first conductive contact 704 and between the third supply line 712 (V_{DDLOC1}) and the second supply line 708 (V_{SS}). Second ESD protection circuitry 720 includes a diode DP72 coupled between the first conductive contact 704 and the third supply line 712, and a diode DN72 coupled between the first conductive contact 704 and second supply line 708. The diode DP72 may be a p-type type diode and the diode DN72 may be an n-type type diode. Second ESD protection circuitry 720 may be coupled with the conductive contact 704 by component L2. In various, embodiments, the component L2 may be an inductor, a capacitor, or a resistor.

In some embodiments, third ESD protection circuitry 716 includes power clamp PC 722 coupled between the first supply line 706 and the second supply line 708. PC 722 may include a variety of different components in different embodiments. PC 722 may comprise any power clamp component described herein.

First circuitry 702 may be a HF switch. First circuitry 702 may take variety of different circuit arrangements and components in different embodiments. In the example illustrated in FIG. 7, first circuitry 702 comprises a first transistor of a first conductivity type and a second transistor of a second conductivity type. The first and second conductivity types are different from one another. In an embodiment, first circuitry 702 comprises an inverter or other transmitter circuitry. First circuitry 702 includes a p-type transistor P1 and an n-type transistor N1. The gate terminal of first transistor P1 is floating. Similarly, the gate terminal of second transistor N1 is floating. The first transistor P1 and the second transistor N1 are coupled in series with each other (at their drain terminals) between the first supply line 706 and the second supply line 708. A body of the first transistor P1 is coupled via p-channel diode (Pch_body_diode) 726 and resistance (R_body_1) 728 with the first supply line 706. A body of the second transistor is coupled via n-channel diode (Nch_body_diode) 730 and resistance (R_body_2) 732 with the second supply line 708. The node 734 where first transistor P1 and the second transistor N1 are coupled is coupled with conductive contact 704. In addition, node 734 serves as an output node that may be coupled to any desired and suitable circuitry (not shown) within the IC device 700. For example, the node 130 may be coupled with a SERDES.

In IC device 700 the on-die power grid is used to decouple first ESD protection circuitry 714 and second stage ESD protection circuitry 720 from first circuitry 702. As mentioned, the on-die power grid of IC device 700 is represented by element R11. Element R11 is coupled between first supply line 706 and third supply line 712. In one example, the on-die power grid provides a resistance of about 10 Ohms.

High frequency (HF) interfaces operate in frequencies in the Gigahertz range. For example, interface circuitry in an HF transceiver can operate in the range of 4 GHz. In a HF interface, it is often necessary to closely couple interface circuitry with the I/O pad. In addition, capacitance at the I/O pad of a HF interface should be small. For example, for a transceiver operating in the GHz range, capacitance should be in the range of 200 fF, with a voltage swing in range of +/−2.5V. In an embodiment, a signal voltage may be a voltage in range of +/−2.5V. In embodiments, a signal voltage may be any voltage in a range of +/−1.0V. up to +/−10.0V. However, known methods for ESD protection typically cannot be used at a HF interface because the junction capacitance is too high. For example, diodes in some known ESD protection circuitry can have capacitance in the range of 1 pF. In addition, a HF interface typically requires low resistance between the I/O pad and interface circuitry. However, some known ESD protection methods may not provide sufficiently low resistance.

Embodiments are directed to a interface circuitry, e.g., a switch, and ESD input protection circuitry co-designed to operate together at high frequencies while providing low capacitance and low resistance at the I/O pad. Embodiments comprise a ballast resistive element with variable resistance coupled between the interface circuitry and the I/O pad. Some embodiments may be implemented in a transceiver with a HF interface. Under normal operating conditions, i.e., normal current and voltage, the resistance value of the resistive element is suitably low for transmitting or receiving HF signals. Under a high current condition, the resistance of the resistive element increases, which increases the voltage drop between the I/O pad and the interface circuitry. According to various embodiments, in a high current condition, a transistor in the interface circuitry is able to handle the lower voltage brought about by the variable resistive element without damage. In some embodiments, resistance under a high current condition increases to double the resistance of current levels under normal operating conditions.

In some embodiments, interface circuitry comprises a switch that operates in the 1-10 GHz range, which comprises a FET or a FinFET. The FET may be susceptible to damage caused by high current and voltage of an ESD event. In some embodiments, the interface circuitry is coupled with the I/O pad via a ballast resistive element with variable resistance. In some embodiments, the gate or body, or both gate and body of a FET are coupled via soft connections to a substrate or bulk. The soft connections may include a ballast resistance. As one of ordinary skill in the art, a “soft” connection generally refers to electrical coupling that does not include metal-to-metal connection, e.g., coupling via a resistive material. In embodiments, a soft-coupled connection may comprise any material used as a transistor substrate material. The resistance value of a soft-coupled connection will depend on at least material properties, transistor size, and transistor geometry. As described below, the FET comprises a parasitic bipolar junction (BJT) transistor. The soft connections to substrate or bulk, and the ballast resistance provide enhanced bipolar ESD current conduction. Additionally, the size of the FET and the current flowing through it is dimensioned correspondingly to high current characteristics of the variable ballast resistive element. In some embodiments, an ESD event corresponds with a current 2.5A or greater and a voltage of 10V or greater. In some embodiments, an ESD event corresponds with CDM or HBM values. During an ESD event, the switch drives the current flowing through the variable resistive element. In one example, current can be on the order of 1A, which may not damage the FET.

In some embodiments, the ballast resistive element with variable resistance is as a single metal shape, without extra spacing surrounding it. In some embodiments, the resistive element is a complex multi-finger structure with keep-out-zones and fill blockage around it to prevent heat dissipation and increase the temperature in the resistive element during the high current of an ESD event.

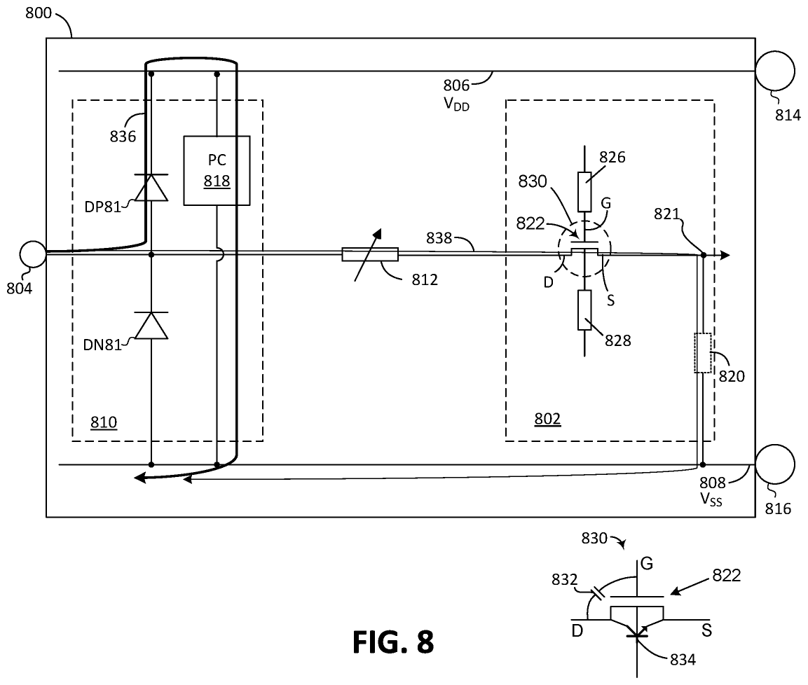

FIG. 8 is a schematic diagram of an IC device comprising interface circuitry and ESD protection circuitry that includes a ballast resistive element with variable resistance, according to some embodiments. As illustrated in FIG. 8, IC device 800 comprises first circuitry 802, first conductive contact 804, first supply line 806, second supply line 808, ESD protection circuitry 810, and variable resistive element 812. First circuitry 802 may be a victim or target to be protected by ESD protection circuitry. First circuitry 802 may be any circuitry or structure to be protected from an ESD event. In various embodiments, first circuitry 802 is an inverter, a HF switch, an input to a HISO receiver, or an input to an LNA. First circuitry 802 may comprise a serial interface. First circuitry 802 may be referred to herein as interface circuitry. The variable resistive element 812 couples the first circuitry 802 with conductive contact 804. IC device 800 also includes a second conductive contact 814, a third conductive contact 816, and a node 821. Node 821 may serve as an output or input node that may be coupled to any desired and suitable circuitry (not shown) within the IC device 800. For example, node 821 may be coupled with a transceiver. In some embodiments, the second conductive contact 814 may be a power supply pad (V_{DD}) and the third conductive contact 816 may be a ground reference voltage (V_{SS}) pad. In embodiments, first conductive contact 804 is an I/O pad for receiving a signal or transmitting a signal.

The first supply line 806 is coupled with second conductive contact 814, and second supply line 808 is coupled with third conductive contact 816. In some embodiments, the first supply line 806 is coupled to provide a supply voltage (V_{DD}) and the second supply line 808 is coupled to provide a ground reference voltage (V_{SS}). The second supply line 808 may also be referred to herein as a ground reference voltage line. Each of first conductive contact 804, second conductive contact 814, and third conductive contact 816 is at a surface of the IC device 800. In embodiments, second conductive contact 814 is a pad for receiving a supply voltage (V_{DD}), and third conductive contact 816 is a pad for receiving a ground reference voltage (V_{SS}). In some embodiments, optional component 820 may be coupled between node 821 and second supply line 808 or first supply line 806. In some embodiments, the component 820 may be omitted. In various embodiments, the component 820 may be an inductor, capacitor, a resistor, a transistor, or any combination of these elements.

In some embodiments, the ESD protection circuitry 810 is coupled with the first conductive contact 804 and between the first supply line (V_{DD}) 806 and the second supply line (V_{SS}) 808. In the example shown in FIG. 8, ESD protection circuitry 810 comprises a diode DP81 coupled between the first conductive contact 804 and the first supply line 806, and a diode DN81 coupled between the first conductive contact 804 and the second supply line 808. The diode DP81 may be a p-type type diode and the diode DN81 may be an n-type type diode. The cathode of the diode DP81 is coupled with the first supply line 806 while the anode of is coupled with first conductive contact 804. The cathode of the diode DN81 is coupled with first conductive contact 804 while the anode of is coupled with the second supply line 808. ESD protection circuitry 810 also includes a power clamp PC 818 coupled between the first supply line 806 and the second supply line 808. The power clamp 818 may include a variety of different components in different embodiments. Power clamps are known in the art and power clamp 818 may be any suitable known power clamp. Power clamp 818 may be any suitable power clamp described elsewhere herein.

In the example illustrated in FIG. 8, first circuitry 802 comprises interface circuitry that comprises a FET or FinFET 822. In an embodiment, transistor 822 is a n-type transistor. In some embodiments, transistor 822 is a p-type transistor. A drain terminal D is coupled with the first conductive contact 804 via resistive element 812. A source terminal S is coupled with node 821, which may be coupled with any desired and suitable circuitry (not shown) within the IC device 800. In some embodiments, the gate G of transistor 822 is connected to a ballast resistance 826 while a second terminal of ballast resistance 826 is coupled with pre-driver circuitry (not shown in the figure). In some embodiments, the body of transistor 822 is connected to a ballast resistance 828 while a second terminal of ballast resistance 828 is coupled with V_{SS} or other reference voltage (not shown in the figure). In one example, the resistive values of each of ballast resistances 826 and ballast resistances 828 is about 10k Ohms. The ballast resistances 826 and ballast resistances 828 may be explicit resistors in some embodiments. In other embodiments, ballast resistances 826 and ballast resistances 828 may be the resistance provided by the substrate or bulk.

FET 822 comprises a parasitic BJT. An enlarged alternative schematic view 830 of FET 822 is depicted in FIG. 8. The view 830 illustrates the parasitic BJT 834 of the npn type present in transistor 822. The collector of BJT 834 is formed by the drain D of the FET, the emitter is formed by the source S, and the base is formed by the body. An analogous parasitic BJT is present in a p-type FET. Miller capacitance 832 includes a resistive-capacitive (RC) component that elevates the voltage of the gate such that the BJT 834 turns on for a short period during the short duration, high current of an ESD event. The current turn-on duration is approximately equal to the Miller capacitance value times the resistance value of the softly-tied gate resistor 828. The soft connections of the gate and body to substrate or bulk increases the conduction of the parasitic BJT 834, which in turn increases ESD current capability of FET 822. In various embodiments, the dimensions of transistor 822 and a corresponding current carrying capacity of the FET are design parameters. The design parameters may be determined in conjunction with current carrying characteristics of variable resistive element 812 so that the current carrying capacity of the parasitic BJT is enhanced.

ESD discharge current paths for a negative CDM stress are indicated by arrows 836 and 838. A primary ESD discharge current 836 flows through diode DP1 and power clamp PC 818. A residual ESD discharge current 838 flows through resistive element 812, transistor 822, and component 820, if present. The primary ESD current 836 is larger than the residual ESD current 838. An advantage of embodiments is that the residual ESD current 838 is of a magnitude that may not damage transistor 822, which may be a CMOS FinFET.

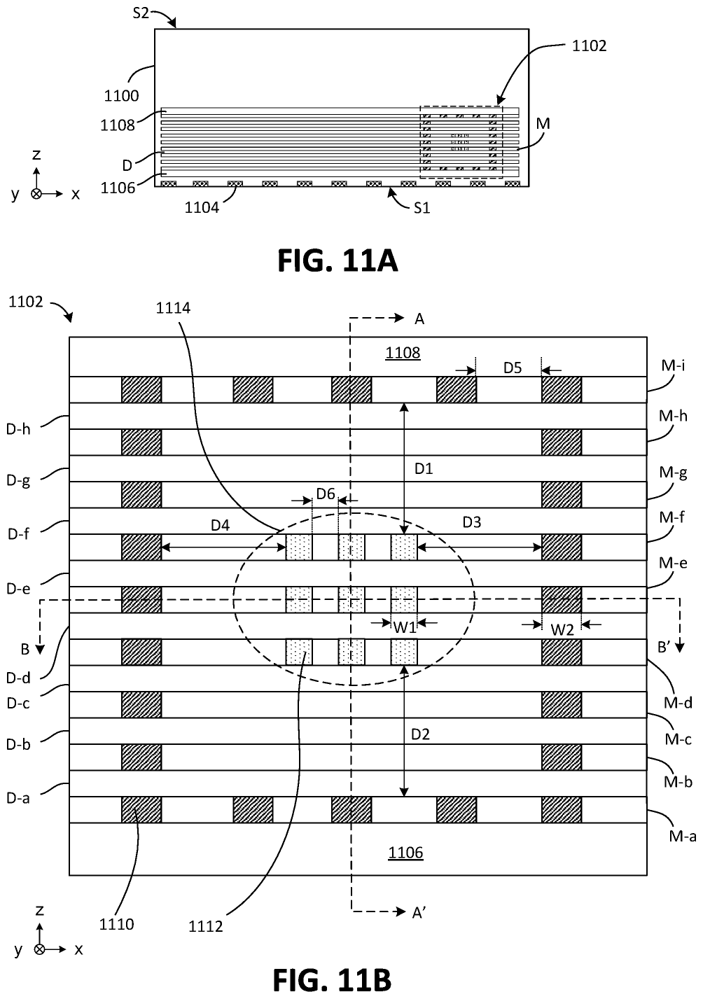

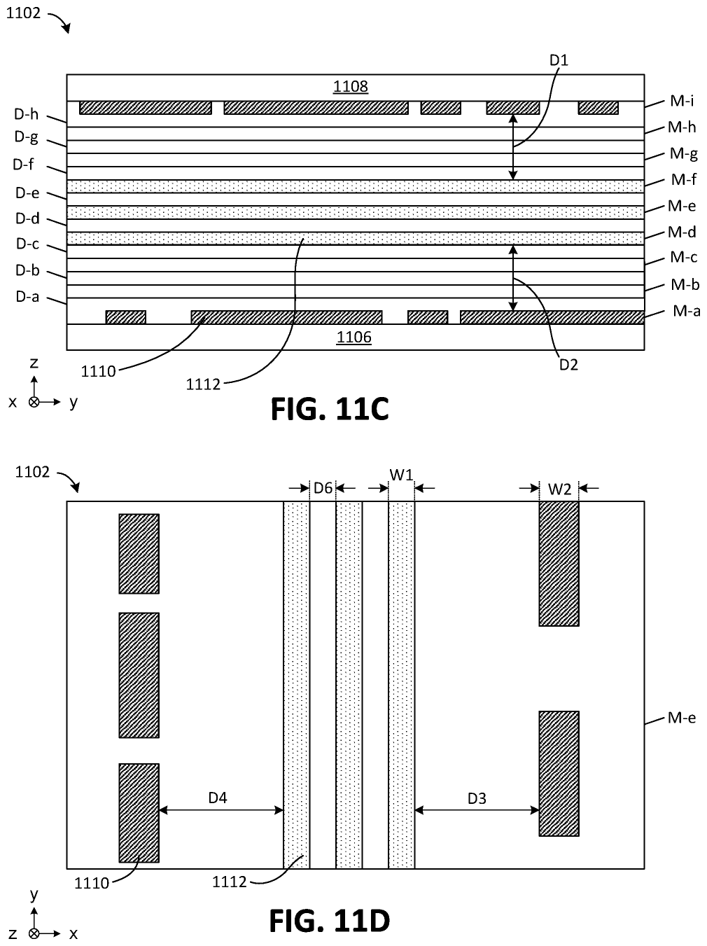

While not shown in FIG. 8, IC device 800 comprises a plurality of alternating metallization and dielectric layers between a first and a second surface opposite the first surface. In some embodiments, variable resistive element 812 comprises one or more traces. The one or more traces may be disposed in one or more of the metallization layers of IC device 800. One example of variable resistive element 812 within metallization layers is described below with reference to FIGS. 11A-C.

Variable resistive element 812 is constructed so the resistance value of resistive element 812 increases under a high current condition, such as an ESD event. The increase in resistance value increases the voltage drop between first conductive contact 804 and first circuitry 802. In embodiments, the voltage drop reduces current to a level such that the transistor 822 is not damaged. Resistive element 812 is comprised of a material having a property of resistance increasing with temperature. Under a high current condition, the material of which resistive element 812 is comprised is heated. In some embodiments, heating of the resistive material under high current is enhanced by insulating material and/or an absence of heat conducting material surrounding resistive element 812. In some embodiments, heating of the resistive material under high current is enhanced by constructing a metal trace with a narrower width or height, or both a narrower width and height than is used for conventional or other traces in the IC. In an example, the resistance value of resistive element 812 increases two-fold under a high current condition. In one example, the resistance value of resistive element 812 increases from 3.6 to 7.2 Ohms under a high current condition. In various embodiments, the resistance value of resistive element 812 may be in the range of 0.1-10 Ohms under a high current condition. Under conditions of a current expected under normal operating conditions, the resistance value of resistive element 812 may be 0.01 to 5 Ohms. In some embodiments, resistive element 812 is comprised of a metal, e.g., copper, aluminum, and/or any other material used to create a feature in a metallization layer. In some embodiments, resistive element 812 is comprised of a polysilicon.

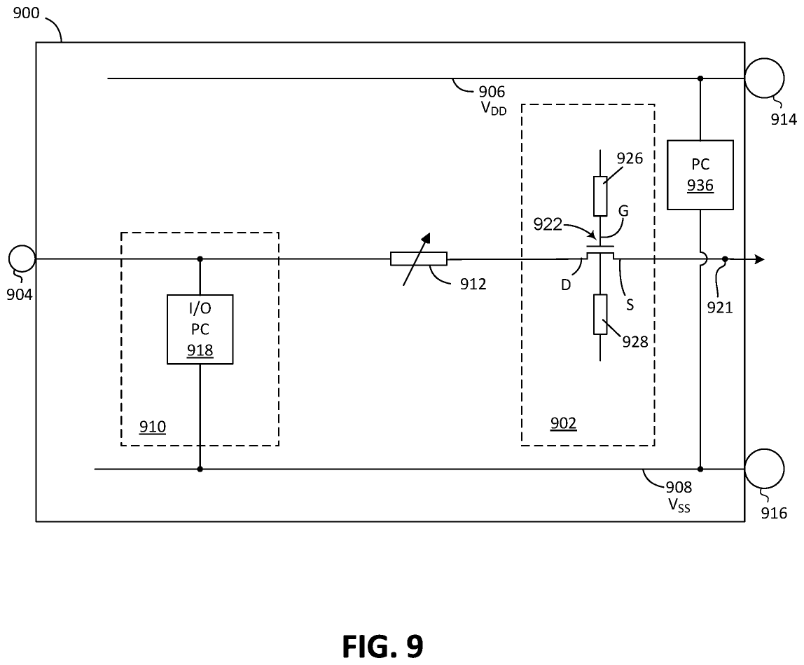

FIG. 9 is a schematic diagram of an IC device comprising interface circuitry and ESD protection circuitry that includes a ballast resistive element with variable resistance, according to some embodiments. As illustrated in FIG. 9, IC device 900 comprises first circuitry 902, first conductive contact 904, first supply line 906, second supply line 908, ESD protection circuitry 910, resistive element 912, and power clamp PC 936. First circuitry 902 may be a victim or target to be protected by ESD protection circuitry. First circuitry 902 may be any circuitry or structure to be protected from an ESD event. In various embodiments, first circuitry 902 is an inverter, a HF switch, an input to a HISO receiver, or an input to an LNA. First circuitry 902 may be referred to herein as interface circuitry. First circuitry 902 may comprise a serial interface. The resistive element 912 is a ballast resistive element with variable resistance that couples the first circuitry 902 with the conductive contact 904. IC device 900 also includes a second conductive contact 914, a third conductive contact 916, and a node 921. Node 921 serves as an input or output node that may be coupled to any desired and suitable circuitry (not shown) within the IC device 900. For example, the output node may be coupled with a transceiver. In some embodiments, the first conductive contact 904 may be an I/O pad, the second conductive contact 914 may be a power supply pad (V_{DD}), and the third conductive contact 916 may be a ground reference voltage (V_{SS}) pad. In embodiments, first conductive contact 904 is an I/O pad for receiving a signal or transmitting a signal.

The first supply line 906 is coupled with a second conductive contact 914, and the second supply line 908 is coupled with a third conductive contact 916. In some embodiments, the first supply line 906 is coupled to provide a supply voltage (V_{DD}) and the second supply line 908 is coupled to provide a ground reference (V_{SS}) voltage. The second supply line 908 may also be referred to herein as a ground reference voltage line. Each of first conductive contact 904, second conductive contact 914, and third conductive contact 916 is at a surface of the IC device 900. In embodiments, second conductive contact 914 may be a pad for receiving a supply voltage (V_{DD}), and third conductive contact 916 may be a pad for receiving a ground reference voltage (V_{SS}). In an embodiment, first conductive contact 904 is an I/O pad for receiving a signal. In an embodiment, first conductive contact 904 is an I/O pad for transmitting a signal.

In some embodiments, the ESD protection circuitry 910 is coupled between the first conductive contact 904 and the second supply line (V_{SS}) 908. In the example shown in FIG. 9, ESD protection circuitry 910 comprises a power clamp PC 918 coupled between the first conductive contact 904 and the second supply line 908. The power clamp 918 may include a variety of different components in different embodiments. Power clamps are known in the art and power clamp 918 may be any suitable known power clamp. In addition, power clamp 918 may be any suitable power clamp described elsewhere herein.

In the example illustrated in FIG. 9, first circuitry 902 comprises interface circuitry that comprises a FET or FinFET 922. In an embodiment, transistor 922 is a n-type transistor. In some embodiments, transistor 922 is a p-type transistor. A drain terminal D is coupled with the first conductive contact 904 via resistive element 912. A second source terminal S is coupled with node 921, which may be coupled with any desired and suitable circuitry (not shown) within the IC device 900. In some embodiments, the gate G of transistor 922 is connected to a ballast resistance 926 while a second terminal of ballast resistance 926 is coupled with pre-driver circuitry (not shown in the figure). In some embodiments, a body of transistor 922 is connected to a ballast resistance 928 while a second terminal ballast resistance 928 is coupled with V_{SS} or other reference voltage (not shown in the figure). In one example, the resistive values of each of ballast resistance 926 and ballast resistance 928 is about 10k Ohms. The ballast resistances 926 and ballast resistances 928 may be explicit resistors in some embodiments. In other embodiments, ballast resistances 926 and ballast resistances 928 may be the resistance provided by the substrate or bulk.

FET 922 comprises a parasitic BJT similar to the parasitic BJT described herein with reference to FET 822. In various embodiments, the dimensions of transistor 922 and a corresponding current carrying capacity of the FET are design parameters. The design parameters may be determined in conjunction with current carrying characteristics of variable resistive element 912 so that the current carrying capacity of the parasitic BJT of FET 922 is enhanced.

Power clamp PC 936 is coupled between first supply line 906 and second supply line 908. The power clamp 936 may include a variety of different components in different embodiments. Power clamps are known in the art and power clamp 936 may be any suitable known power clamp. In addition, power clamp 936 may be any suitable power clamp described elsewhere herein.

While not shown in FIG. 9, IC device 900 comprises a plurality of alternating metallization and dielectric layers between a first and a second surface opposite the first surface. Variable resistive element 912 comprises one or more traces. The one or more traces may be disposed in one or more of the metallization layers of IC device 900. One example of resistive element 912 within metallization layers is described below with reference to FIGS. 11A-C. In some embodiments, the resistive element 912 may be the same as or similar to resistive element 812. Like variable resistive element 812, resistive element 912 is constructed so the resistance value of resistive element 912 increases under a high current condition, such as an ESD event. Resistive element 912 may be surrounded by insulating material and/or an absence of heat conducting material. Resistive element 912 may comprise a trace with a narrower width or height, or both a narrower width and height than is used for other traces in the IC. Resistive element 912 may comprise two or more adjacent traces that radiate heat toward each other.

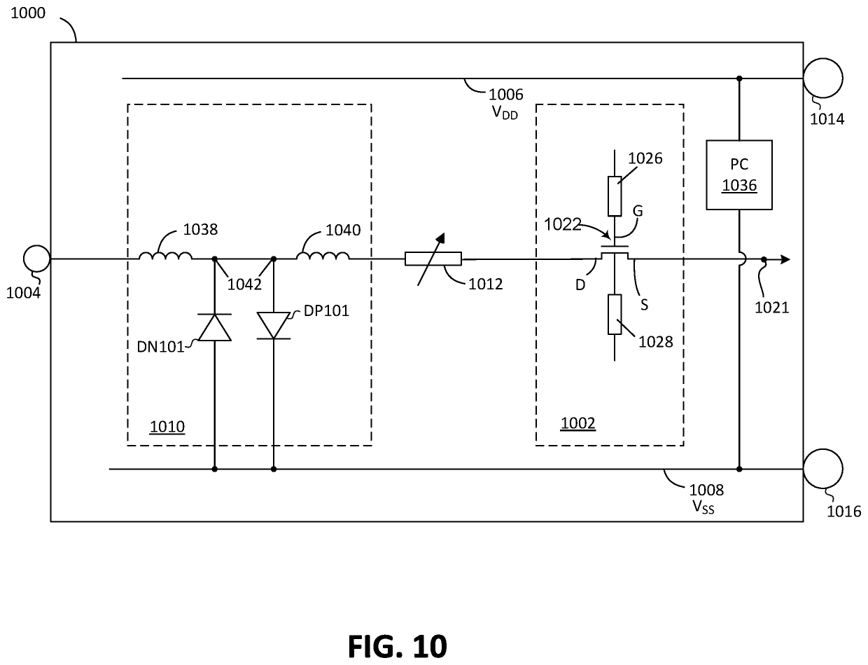

FIG. 10 is a schematic diagram of an IC device comprising interface circuitry and ESD protection circuitry that includes a ballast resistive element with variable resistance, according to some embodiments. As illustrated in FIG. 10, IC device 1000 comprises first circuitry 1002, first conductive contact 1004, first supply line 1006, second supply line 1008, ESD protection circuitry 1010, resistive element 1012, and power clamp PC 1036. First circuitry 1002 may be a victim or target to be protected by ESD protection circuitry. First circuitry 1002 may be any circuitry or structure to be protected from an ESD event. In various embodiments, first circuitry 1002 is an inverter, a HF switch, an input to a HISO receiver, or an input to an LNA. First circuitry 1002 may be referred to herein as interface circuitry. First circuitry 1002 may comprise a serial interface. The resistive element 1012 couples the first circuitry 1002 with the conductive contact 1004. IC device 1000 also includes a second conductive contact 1014, a third conductive contact 1016, and a node 1021. Node 1021 may serve as an input or output node that may be coupled to any desired and suitable circuitry (not shown) within the IC device 1000. For example, the node 1021 may be coupled with a transceiver. In some embodiments, the second conductive contact 1014 may be a power supply pad (V_{DD}), and the third conductive contact 1016 may be a ground reference voltage (V_{SS}) pad. In embodiments, first conductive contact 1004 is an I/O pad for receiving a signal or transmitting a signal.

The first supply line 1006 is coupled with a second conductive contact 1014, and the second supply line 1008 is coupled with a third conductive contact 1016. In some embodiments, the first supply line 1006 is coupled to provide a supply voltage (V_{DD}) and the second supply line 1008 is coupled to provide a ground reference voltage (V_{SS}). The second supply line 1008 may also be referred to herein as a ground reference voltage line. Each of first conductive contact 1004, second conductive contact 1014, and third conductive contact 1016 is at a surface of the IC device 1000. In embodiments, second conductive contact 1014 may be a pad for receiving a supply voltage (V_{DD}) and third conductive contact 1016 may be a pad for receiving a ground reference voltage (V_{SS}). In an embodiment, first conductive contact 1004 is an I/O pad for receiving a signal. In an embodiment, first conductive contact 1004 is an I/O pad for transmitting a signal.

In some embodiments, the ESD protection circuitry 1010 is coupled between the first conductive contact 1004 and the second supply line 1008 (V_{SS}). In the example shown in FIG. 10, ESD protection circuitry 1010 comprises a first inductor 1038 and a second inductor 1040 coupled in series at a node 1042 between the first conductive contact 1004 and the resistive element 1012. In addition, ESD protection circuitry 1010 includes a diode DP101 coupled between the first conductive contact 1004 and the second supply line 1008, and a diode DN101 coupled between the first conductive contact 1004 and the second supply line 1008. In an embodiment, the diode DP101 may be a p-type type diode and the diode DN101 may be an n-type type diode. In various embodiments, diode DP101 may be a n-type type diode and/or diode DN101 may be a p-type diode. In the example shown in FIG. 10, the anode of the diode DP101 is coupled with the first conductive contact 1004 at node 1042 while the cathode of is coupled with the second supply line 1008. In FIG. 10, the cathode of the diode DN101 is coupled with first conductive contact 1004 at node 1042 while the anode is coupled with the second supply line 1008.

In the example illustrated in FIG. 10, first circuitry 1002 comprises interface circuitry that comprises a FET or FinFET 1022. In an embodiment, transistor 1022 is a n-type transistor. In some embodiments, transistor 1022 is a p-type transistor. A drain terminal D is coupled with the first conductive contact 1004 via resistive element 1012. A second source terminal S is coupled with node 1021, which may be coupled any desired and suitable circuitry (not shown) within the IC device 1000. In some embodiments, the gate G of transistor 1022 is connected to a ballast resistance 1026 while a second terminal of ballast resistance 1026 is coupled with pre-driver circuitry (not shown in the figure). In some embodiments, a body of transistor 1022 is connected to a ballast resistance 1028 while a second terminal ballast resistance 1028 is coupled with V_{SS} or other reference voltage (not shown in the figure). In one example, the resistive values of each of ballast resistance 1026 and ballast resistance 1028 is about 10k Ohms. The ballast resistances 1026 and ballast resistances 1028 may be explicit resistors in some embodiments. In other embodiments, ballast resistances 1026 and ballast resistances 1028 may be the resistance provided by the substrate or bulk.

FET 1022 comprises a parasitic BJT similar to the parasitic BJT described herein with reference to FET 822. In various embodiments, the dimensions of transistor 1022 and a corresponding current carrying capacity of the FET are design parameters. The design parameters may be determined in conjunction with current carrying characteristics of variable resistive element 1012 so that the current carrying capacity of the parasitic BJT of FET 1022 is enhanced.

In some embodiments, power clamp PC 1036 is coupled between first supply line 1006 and second supply line 1008. The power clamp 1036 may include a variety of different components in different embodiments. Power clamps are known in the art and power clamp 1036 may be any suitable known power clamp. In addition, power clamp 1036 may be any suitable power clamp described elsewhere herein.

While not shown in FIG. 10, IC device 1000 comprises a plurality of alternating metallization and dielectric layers between a first and a second surface opposite the first surface. Variable resistive element 1012 comprises one or more traces. The one or more traces may be disposed in one or more of the metallization layers of IC device 1000. One example of resistive element 1012 within metallization layers is described below with reference to FIGS. 11A-C. The resistive element 1012 is a variable resistor. The resistive element 1012 may be the same as or similar to resistive element 812. Like variable resistive element 812, resistive element 1012 is constructed so the resistance value of resistive element 1012 increases under a high current condition, such as an ESD event. Resistive element 1012 may be surrounded by insulating material and/or an absence of heat conducting material. Resistive element 1012 may comprise a trace with a narrower width or height, or both a narrower width and height than is used for other traces in the IC. Resistive element 1012 may comprise two or more adjacent traces that radiate heat toward each other.

FIG. 11A is a cross-sectional illustration of an IC die comprising a resistive element with variable resistance in a region of the IC die, according to some embodiments. IC die 1100 comprises a plurality of alternating metallization layers M and dielectric layers D between a first surface S1 and a second surface S2. As shown in FIG. 11A, second surface S2 is opposite first surface S1. IC die 1100 comprises a plurality of conductive contacts 1104 at first surface S1. Additionally, or alternatively, IC die 1100 may comprise a plurality of conductive contacts at second surface S2. The alternating metallization layers M and dielectric layers D are between levels 1106 and 1108. Levels 1106 and 1108 may comprise device layers or dielectric material. A region 1102 includes a ballast resistive element with variable resistance in accordance with some embodiments. While not shown in FIG. 11A, in some embodiments, the IC die 1100 may comprise any of the interface circuitry, ESD protection circuitry, supply lines, and conductive contacts described herein. As one example, IC die 1100 comprises ESD protection circuitry 810 and interface circuitry 802.

FIG. 11B is a cross-sectional, enlarged illustration of the region of IC die illustrated in FIG. 11A, according to some embodiments. As illustrated in FIG. 11B, the region 1102 includes metallization layers M-a through M-i. In other embodiments, the IC die may include any number of metallization layers. Respective metallization layers are separated by dielectric layers, e.g., dielectric layers D-a through D-h. The metallization layers include metal features or conductive traces 1110, which in some embodiments may be metal routing or metal fill. In addition, metallization layers M-d, M-e, and M-f include conductive features or traces 1112, which together comprise a resistive element 1114 in accordance with some embodiments. While not shown in FIG. 11B, the resistive element 1114 is coupled between a conductive contact at a surface of the IC die and first circuitry within the IC die, as described elsewhere herein. Nine conductive traces 1112 on three metallization layers are illustrated in FIG. 11B. However, this is not required. In some embodiments, one or more conductive traces 1112 may be on more or fewer metallization layers. In some embodiments, one or more conductive traces 1112 may be on a single metallization layer. In an embodiment, the resistive element 1114 comprises a single conductive trace 1112 on a single metallization layer. In some embodiments, the resistive element 1114 is comprised of a metal, e.g., copper, aluminum, or any other material used to create a feature in a metallization layer. In some embodiments, resistive element 1114 is comprised of a polysilicon. The dielectric layers may be organic dielectrics.

Conductive features 1110 can have a width W2. In contrast, in some embodiments, conductive traces 1112 may have a width W1, which is less than W2. In some embodiments, width W1 may be between 10 nm and 10 μm. In some embodiments, width W2 may be between 10 nm and 10 μm. For two lines of equal length but different widths, the narrower width trace provides a higher resistance than the wider trace. For equal current, a narrower trace generates more heat than a wider trace during conduction. An advantage of conductive traces 1112 with the width W1 is that under a high current condition, e.g., during an ESD event, they may generate more heat than if they had the width W2. This facilitates resistive element 1114 in providing a resistance that increases under high current condition. In an embodiment, a via or other structure that couples conductive traces 1112 with a conductive contact at a surface of the IC die. In an embodiment, resistive element 1114 comprises such a via or other structure coupling a conductive trace 1112 with a conductive contact.

In some embodiments, conductive traces 1112 may have a height (z-axis) that is less than height of conductive traces 1110.

The metallization layer M-i may include metal features 1110 that overlap with the conductive traces 1110 in other metallization layers, e.g., M-f. The metallization layer M-i may also include some metal features 1110 that overlap with the conductive traces 1112 in metallization layer M-f. However, portions of the metallization layers M-g and M-h above and overlapping the conductive traces 1112 in metallization layer M-f are free of metal features 1110. These portions may be referred to as “skip layers” or a “keep out” zone. These portions may also be referred to as “dielectric zones” or simply “zones.” The dielectric zones provide additional insulation in comparison to if metal features were included in metallization layers M-g and M-h above and overlapping conductive traces 1112. In the example of FIG. 11B, dielectric zones are on all sides of the conductive traces 1112. The span of one of the dielectric zones is D1, which is the distance between metallization layer M-f and vertically adjacent (z-direction) metallization layer M-i. The dielectric zone corresponding with D1 comprises three dielectric layers (D-f, D-g, and D-h) and two metallization layers (M-h and M-g). However, in other embodiments, a dielectric zone may span a distance corresponding with fewer layers. In an embodiment, conductive traces 1112 in are in first metallization layer, e.g., M-f, a first dielectric layer, e.g., D-f, is adjacent to the first metallization layer, and a second metallization layer, e.g., M-g, is adjacent to the first dielectric layer. In this embodiment, the z-axis dielectric zone above the conductive traces 1112 in metallization layer m-f is equal to or greater than a distance equal to a sum of a height of a first dielectric layer D-f and metallization layer M-g. In an embodiment, the z-axis dielectric zone above conductive traces 1112 in metallization layer m-f corresponds with at least one dielectric layer (D-f) and one metallization layer (M-g). In another embodiment, the z-axis dielectric zone above conductive traces 1112 in metallization layer m-f corresponds with at least two dielectric layers (D-f and D-g) and one metallization layer (M-g). For example, the height of a dielectric zone is at least equal to a sum of the heights of M-g, D-f, and D-g. In FIG. 11B, the height of the dielectric zone corresponding with D1 equal to the sum of D-f, M-g, D-g, M-h, and D-h.

In the example shown in FIG. 11B, the portions of two metallization layers (M-g, M-h) that are above and overlapping conductive traces 1112 are metal free. However, in other embodiments, only one metallization layer comprising a portion above and overlapping conductive traces 1112 that is metal free may be provided. In some embodiments, more than two metallization layers with metal-free portions may be provided as a keep out zone. A dielectric zone comprises the one or more metallization layers with metal-free portions above and overlapping conductive traces 1112. The dielectric zone also comprises dielectric layers adjacent to the one or more metallization layers. In an embodiment, the height of a metallization layer is between 10 nm and 100 μm. In some embodiments, the height of a dielectric layer is between 10 nm and 100 μm.

In FIG. 11B, the height of another dielectric zone is D2, which is the distance between metallization layer M-d and vertically adjacent (z-direction) metallization layer M-a. The span of the dielectric zone corresponding with D2 equal to the sum of D-c, M-c, D-b, M-b, and D-a. In other embodiments, the span of the dielectric zone corresponding with D2 may comprise more or fewer metallization and dielectric layers.

An advantage of a dielectric zone above (or below) and overlapping a conductive trace 1110 of a resistive element 1114 is that during a high current condition, e.g., an ESD event, conductive traces 1110 may become hotter than if a metal feature were present in a vertically adjacent metallization layer. This facilitates resistive element 1114 in providing a resistance that increases with temperature.

As shown in FIG. 11B, a dielectric zone may also be provided on either or both sides of resistive element 1114. A resistive element 1114 comprises a conductive trace 1110 in a particular dielectric layer. In some embodiments, a dielectric zone comprises a portion of the particular dielectric layer proximate to the conductive trace 1110. For example, a dielectric zone can comprise a portion of a dielectric layer horizontally (x-axis) adjacent to a conductive trace 1110.

In FIG. 11B, a dielectric zone of width D3 is on the right side of resistive element 1114. The right-side, x-axis dielectric zone is between a conductive trace 1112 in layer M-f and a metal feature 1110 in layer M-f. In the shown example, this dielectric zone also includes between conductive traces 1112 in metallization layers M-d and M-e and metal features 1110 in metallization layers M-d and M-e. In embodiments, the zone corresponding with D3 may span a horizontal (x-axis) distances that are substantially the same as the vertical (z-axis) distances D1 and D2 described herein. Similarly, FIG. 11B illustrates a dielectric zone of width D4 is on the left side of resistive element 1114. The left-side, x-axis dielectric zone is between conductive traces 1112 in metallization layers M-f, M-e, and M-d and metal features 1110 in metallization layers M-f, M-e, and M-d. In embodiments, the zone corresponding with D4 may span a horizontal (x-axis) distances that are substantially the same as the vertical (z-axis) distances D1 and D2 described herein. The dielectric zones on the right and left sides of resistive element 1114 may be occupied by a dielectric material instead of a metal feature. Portions of metallization layers M-g and M-h directly above these right- and left-side dielectric zones may also be metal free, as shown in the figure. In a like manner, portions of metallization layers M-c and M-b directly below these right- and left-side dielectric zones may also be metal free, as shown in the figure.

As may be seen in FIG. 11B, the distance D5 horizontally (x direction) separates one metal feature 1110 from another metal feature 1110 in layers M-a and M-i. The distance D5 may be a minimum distance between metal features provided in a design rule. In contrast to the distance D5, the widths of dielectric zones D3 and D4 may be greater than width D5. In some embodiments, one or both of widths D3 and D4 may be the same as heights D1 or D2. For example, the width of a right- or left-side dielectric zone is at least equal to a sum of the heights of metallization layer M-g, and dielectric layers D-f, and D-g. As another example, the width of a right- or left-side dielectric zone is at least equal to a sum of the heights of metallization layers M-g and M-h, and dielectric layers D-f, D-g, and D-h. In an embodiment, the width of a right- or left-side dielectric zone is between 10 μm and 100 μm.

The right- and left-side dielectric zone corresponding with widths D3 and D4 provide additional spacing, e.g., keep out zone, between horizontally adjacent metal features in the same layer. Advantageously, this additional spacing inhibits heat dissipation during a high current condition, e.g., an ESD event, allowing conductive traces 1112 to become hotter than if a metal feature were more closely adjacent in a same layer.

Conductive traces 1112 of resistive element 1114 may be spaced relatively close together. In FIG. 11B, the distance D6 separates conductive traces 1112 in a same layer. The distance D6 may be less that the distance D5 that separates metal features 1110 in a layer, such as layer M-i. The relatively closely spaced metal traces 1112 facilitates heating of conductive traces 1110 during a high current condition, such as an ESD event.

FIG. 11C is a cross-sectional illustration of the region of the IC die in FIG. 11B along line A-A,′ according to some embodiments. As shown in FIG. 11C, metal traces 1112 of resistive element 1114 extend along the Y-direction in metallization layers M-d, M-e, and M-f. In addition, metal features 1110 extend along the Y-direction in metallization layers M-a and M-i. Metallization layers M-b and M-c are vertically adjacent to metallization layer M-d. Similarly, metallization layers M-g, and M-h are vertically adjacent to metallization layer M-f. In embodiments, dielectric zones (or keep out zones) are free of metal features 1110 in portions of metallization layers M-b, M-c, M-g, and M-h that overlap conductive traces 1112. Dielectric zones in layers M-b, M-c, M-g, and M-h are also free of material that has a heat dissipation property similar to a metal.

FIG. 11D is a cross-sectional illustration of the region of the IC die in FIG. 11B along line B-B,′ according to some embodiments. As shown in FIG. 11D, metal features 1110 and conductive traces 1112 extend along the Y-direction in metallization layer M-e. Dielectric zones are disposed in portions of metallization layer M-e on the right and left sides of conductive traces 1112. In the figure, the widths of the dielectric zones are given by D3 and D4. The widths D3 and D4 are each greater that the distance D5 between horizontally adjacent to conductive traces 1112. The distances D3 and D4 are also greater than the width W2 of metal features 1110. In some embodiments, the distances D3 and D4 are greater than the width W2 of metal features 1110 by a factor of 5 or 10, e.g., D3>5×W2, or D3>10×W2.

In in FIGS. 11A-D, resistive element 1114 comprises a plurality of conductive traces 1112 extending along one axis. However, this is not required. In some embodiments, resistive element 1114 comprises a conductive trace that meanders. A conductive trace may include turns. For example, within a single layer, a conductive trace may extend for a first distance along the y-axis and a second distance along the x axis. A conductive trace may include vertically extending portions or vias between layers. As an example, a resistive element 1114 may comprise a conductive trace having a first segment extending along the y axis in a first layer and a second segment extending along the x axis in a second layer, wherein the first and second segments are connected by a via extending along the z axis. In some embodiments, resistive element 1114 comprises a plurality of fingers, each finger having a different shape.

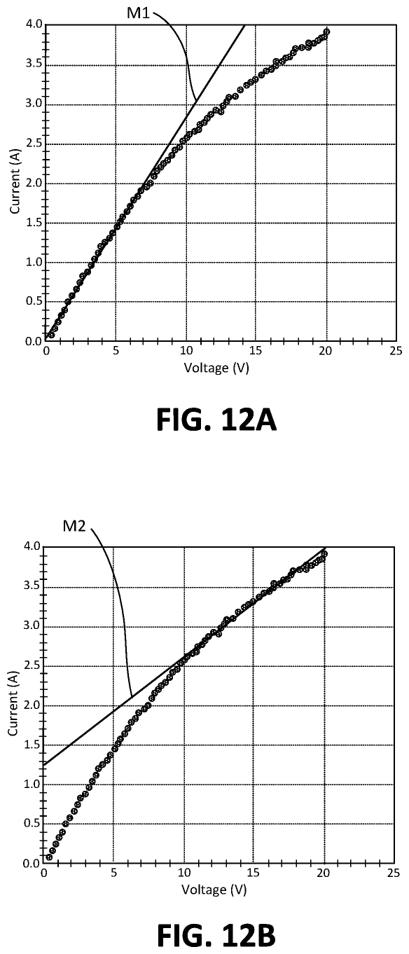

FIGS. 12A and 12B are graphs of illustrating transmission line pulse (TLP) voltages over a range of current values applied to a resistive element with variable resistance, according to some embodiments. The graphs may be used to determine resistive values for high and low current values. The measurements are made with a TLP pulse width of Ins and a rise time of 100 ps. FIG. 12A shows line M1 that is determined by a least-squares regression method over a low current regime for an example resistive element. FIG. 12B shows line M2 similarly determined over a high current regime for the example resistive element. In some embodiments, the example resistive element is resistive element 812, 912, 1012, or 1114. The inverse of the slope of the lines M1 and M2 represent resistance values for the example resistive element. As shown in FIG. 12A, the resistance value the example resistive element in 0.0-2.0V regime is approximately 3.6 Ohms. As shown in FIG. 12B, the resistance value the example resistive element in 2.5-4.0V regime is approximately 7.2 Ohms. In the context of resistance values, “approximately” means within +/−0.5 ohms. An advantage of the resistive elements 812, 912, 1012, or 1114 is that the resistance increases from 3.6 to 7.2 Ohms under high currents due to increased temperature of conductive traces from which the resistive element is comprised.

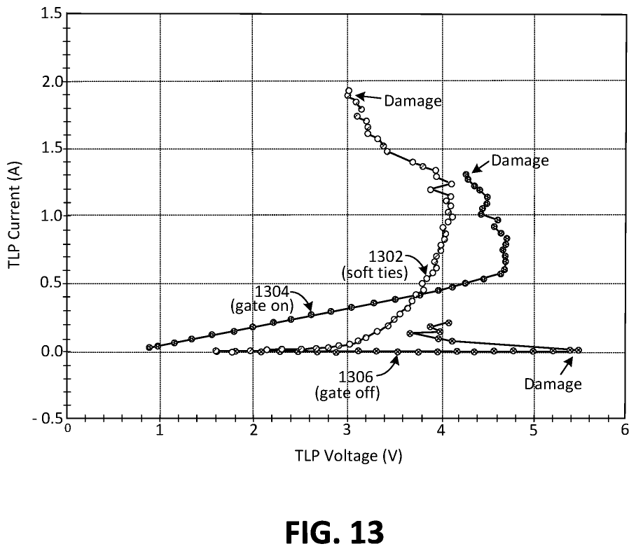

FIG. 13 is a graph illustrating TLP measurements of a stand-alone high-frequency switch with different gate and bulk connections, according to some embodiments. The switch may be, for example, transistor 822, 922, or 1022. Line 1302 represents measurements taken with both the bulk and gate of the transistor softly tied via 10k Ohms of resistance to substrate or bulk. As shown by line 1302, damage to the switch with gate and body softly coupled to substrate from a TLP occurs at about 1.9 amps. Line 1304 represents measurements taken with the gate connected to the drain so that the transistor is on. In the on configuration and without soft coupling, damage to the switch from a TLP occurs at about 1.3 amps. Line 1306 represents measurements taken with the gate connected to the source so that the transistor is off. In this configuration and without soft coupling, damage to the switch from a TLP occurs at about 5.5 volts and 0.0 amps. It may be seen from FIG. 13 that an advantage of softly tying the body and gate of the high-frequency switch to the substrate via 10k Ohms of resistance is that a higher current may be sustained without causing damage as compared to configurations where the transistor is tied on or off and without soft coupling.

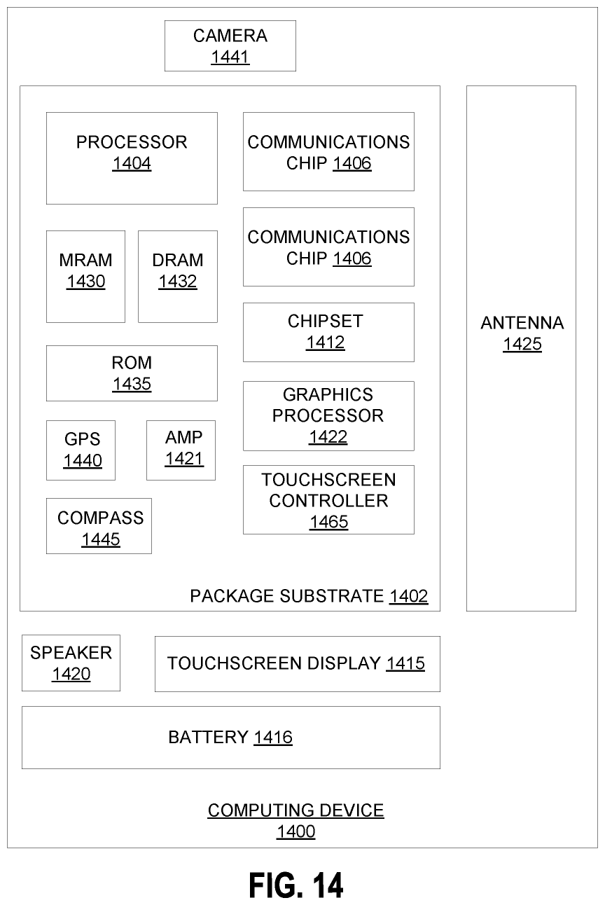

FIG. 14 is a functional block diagram of an electronic computing device 1400, in accordance with an embodiment of the present invention. Device 1400 further includes a package substrate 1402 hosting a number of components, such as, but not limited to, a processor 1404 (e.g., an applications processor). Processor 1404 may be physically and/or electrically coupled to package substrate 1402. In some examples, processor 1404 is within an IC die that comprises interface circuitry and ESD protection circuitry employing first, second, and third supply lines. For example, the IC die may be IC device 100, 201, 300, 401, 501, 600, or 700. In some examples, processor 1404 is within an IC die that comprises interface circuitry and ESD protection circuitry that includes a ballast resistive element with variable resistance, according to some embodiments. For example, the IC die may be IC die 800, 900, or 1000. In general, the term “processor” or “microprocessor” may refer to any device or portion of a device that processes electronic data from registers and/or memory to transform that electronic data into other electronic data that may be further stored in registers and/or memory.

In various examples, one or more communication chips 1406 may also be physically and/or electrically coupled to the package substrate 1402. In embodiments, one or more communication chips 1406 comprise an HF interface. In further implementations, communication chips 1406 may be part of processor 1404. Depending on its applications, computing device 1400 may include other components that may or may not be physically and electrically coupled to package substrate 1402. These other components include, but are not limited to, volatile memory (e.g., DRAM 1432), non-volatile memory (e.g., ROM 1435), flash memory (e.g., NAND or NOR), magnetic memory (MRAM 1430), a graphics processor 1422, a digital signal processor, a crypto processor, a chipset 1412, an antenna 1425, touchscreen display 1415, touchscreen controller 1465, battery 1416, audio codec, video codec, power amplifier 1421, global positioning system (GPS) device 1440, compass 1445, accelerometer, gyroscope, speaker 1420, camera 1441, and mass storage device (such as hard disk drive, solid-state drive (SSD), compact disk (CD), digital versatile disk (DVD), and so forth), or the like. In an embodiment, computing device 1400 may include a SERDES. In some exemplary embodiments, at two of the functional blocks noted above are within a composite IC chip structure including a chiplet bonded to a host IC chip, for example as described elsewhere herein. For example, processor 1404 may be implemented within circuitry in a first IC die, and an electronic memory (e.g., MRAM 1430 or DRAM 1432) may be implemented with circuitry in a second IC die.

Communication chips 1406 may enable wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1406 may implement any of a number of wireless standards or protocols. As discussed, computing device 1400 may include a plurality of communication chips 1406. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

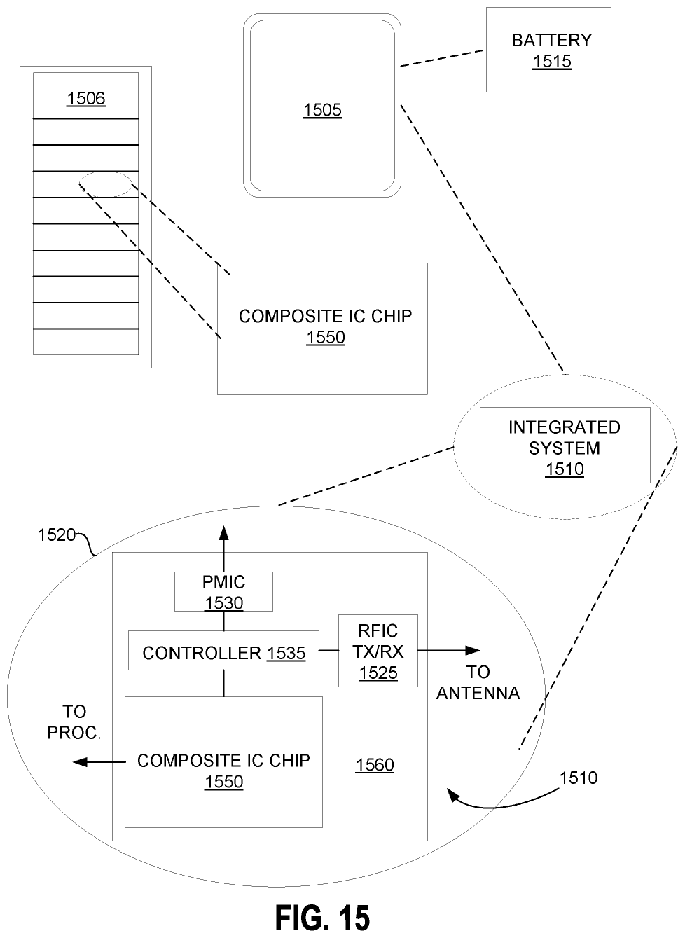

FIG. 15 illustrates a mobile computing platform and a data server machine employing IC die that comprises interface circuitry and ESD protection circuitry employing first, second, and third supply lines, for example as described elsewhere herein. For example, the IC die may be IC device 100, 201, 300, 401, 501, 600, or 700. In some examples, the IC die employed by the mobile computing platform and data server machine comprises interface circuitry and ESD protection circuitry that includes a ballast resistive element with variable resistance, according to some embodiments. For example, the IC die may be IC die 800, 900, or 1000. Computing device 1100 may be found inside platform 1505 or server machine 1506, for example. The server machine 1506 may be any commercial server, for example including any number of high-performance computing platforms disposed within a rack and networked together for electronic data processing, which in the exemplary embodiment includes an IC die that comprises: interface circuitry and ESD protection circuitry employing first, second, and third supply lines. In some embodiments, the IC die further comprises interface circuitry and ESD protection circuitry that includes a ballast resistive element with variable resistance, for example as described elsewhere herein. The mobile computing platform 1505 may be any portable device configured for each of electronic data display, electronic data processing, wireless electronic data transmission, or the like. For example, the mobile computing platform 1505 may be any of a tablet, a smart phone, laptop computer, etc., and may include a display screen (e.g., a capacitive, inductive, resistive, or optical touchscreen), a chip-level or package-level integrated system 1510, and a battery 1515.

Whether disposed within the integrated system 1510 illustrated in the expanded view 1520, or as a stand-alone package within the server machine 1506, composite IC chip 1550 may include interface circuitry and ESD protection circuitry employing first, second, and third supply lines and/or interface circuitry and ESD protection circuitry that includes a ballast resistive element with variable resistance, for example as described elsewhere herein. Composite IC chip 1550 may be further coupled to a host substrate 1560, along with, one or more of a power management integrated circuit (PMIC) 1530, RF (wireless) integrated circuit (RFIC) 1525 including a wideband RF (wireless) transmitter and/or receiver (TX/RX) (e.g., including a digital baseband and an analog front-end module further comprises a power amplifier on a transmit path and a low noise amplifier on a receive path), and a controller 1535. PMIC 1530 may perform battery power regulation, DC-to-DC conversion, etc., and so has an input coupled to battery 1515 and with an output providing a current supply to other functional modules. As further illustrated, in the exemplary embodiment, RFIC 1525 has an output coupled to an antenna (not shown) to implement any of a number of wireless standards or protocols, including but not limited to Wi-Fi (IEEE 902.11 family), WiMAX (IEEE 902.16 family), IEEE 902.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An integrated circuit (IC) device comprising: a conductive contact at a surface of the IC device; a resistive element coupled between the conductive contact and first circuitry; second circuitry coupled between the resistive element and the conductive contact, wherein the second circuitry is further coupled with a supply line and comprises at least one of a diode or a power clamp; a first metallization layer, wherein the resistive element is disposed in the first metallization layer; a first dielectric layer adjacent to the first metallization layer, and a second metallization layer adjacent to the first dielectric layer, wherein a height of the first dielectric layer and the second metallization layer is a first distance; and a zone overlapping the resistive element, and extending a second distance away from the resistive element, wherein the zone is free of conductive material and the second distance is greater than the first distance.

Example 2: The IC device of example 1, wherein a resistance of the resistive element increases in response to an electrostatic discharge (ESD) event to protect the first circuitry.

Example 3: The IC device of example 1, wherein a resistance of the resistive element comprises a first resistance value in response to a first voltage at the conductive contact, and a second resistance value in response to a second voltage at the conductive contact, wherein the second resistance value is higher than the first resistance value.

Example 4: The IC device of example 3, wherein the second voltage is greater than 2.5 volts and the second resistance value is about 7.2 ohms, and the first voltage is less than 2.0 volts and the first resistance value is about 3.1 ohms.

Example 5: The IC device of any of examples 1 through 4, further comprising a first trace comprising a first width in the first metallization layer, wherein the resistive element comprises a second trace in the first metallization layer comprising a second width, and the second width is less than the first width.

Example 6: The IC device of any of examples 1 through 4, further comprising a first trace and a second trace adjacent to the first trace in a same metallization layer, wherein the first trace is separated from the second trace by a third distance; and wherein the resistive element comprises a third trace and a fourth trace adjacent to the third trace in the first metallization layer, wherein the third trace is separated from the fourth trace by a fourth distance, and the fourth distance is less than the third distance.

Example 7: The IC device of any of examples 1 through 4, further comprising a third metallization layer adjacent to the first metallization layer and on a side of the first metallization layer opposite the second metallization layer, wherein the resistive element comprises a first trace in the first metallization layer and a second trace in the third metallization layer.

Example 8: The IC device of any of examples 1 through 7, wherein the first circuitry comprises a transistor.

Example 9: The IC device of example 8, wherein a gate of the transistor is soft-coupled with a bulk and a substrate of the transistor is soft-coupled with the bulk.

Example 10: The IC device of any of examples 1 through 9, wherein the supply line is a first supply line, the first circuitry comprises an output node and a component, and the component is coupled between the output node and at least one of the first supply line or a second supply line, wherein the component comprises at least one of an inductor, a capacitor, a resistor, or a transistor.

Example 11: The IC device of example 1, wherein the first circuitry comprises at least one of a switch, a receiver, a transmitter, an inverter, a serializer-deserializer, or an amplifier.

Example 12: The IC device of any of example 1 through example 11, wherein the supply line is a first supply line, the second circuitry is to protect the first circuitry from an electrostatic discharge (ESD) event, and the power clamp is a first power clamp, the second circuitry comprising: the first supply line; a second supply line; a first diode coupled between the conductive contact and the first supply line; a second diode coupled between the conductive contact and the second supply line; and a second power clamp coupled between the first supply line and the second supply line.

Example 13: The IC device of any of example 1 through example 11, wherein the supply line is a first supply line, the second circuitry is to protect the first circuitry from an electrostatic discharge (ESD) event, and the power clamp is a first power clamp, the second circuitry comprising: the first supply line; a second supply line; and a second power clamp coupled between the conductive contact and at least one of the first supply line or the second supply line.

Example 14: The IC device of any of example 1 through example 11, wherein the supply line is a first supply line, and the second circuitry is to protect the first circuitry from an electrostatic discharge (ESD) event, the second circuitry comprising: the first supply line; a second supply line; a first diode comprising a first cathode coupled at a node with the conductive contact and a first anode coupled with the second supply line; a second diode comprising a second anode coupled at the node with the conductive contact and a second cathode coupled with the second supply line; and a first inductor coupled between the conductive contact and the node, and a second inductor coupled between the resistive element and the node.

Example 15: The IC device of any of example 1 through example 14, wherein the zone comprises a portion of the first metallization layer laterally adjacent to the resistive element.

Example 16: A system comprising: a memory coupled with a microprocessor; an integrated circuit (IC) device coupled with at least one of the memory or the microprocessor, wherein the IC device comprises:
electrostatic discharge (ESD) protection circuitry to protect first circuitry, wherein the ESD protection circuitry is coupled with a conductive contact at a surface of the IC device, and coupled with at least one of a first supply line to provide a first voltage or a second supply line to provide a ground reference voltage; a resistive element coupled between the conductive contact and the first circuitry, wherein a resistance of the resistive element increases in response to an ESD event to protect the first circuitry, and the resistive element is disposed in a first metallization layer; a first dielectric layer adjacent to the first metallization layer, wherein a height of the first dielectric layer and the first metallization layer is a first distance; and a zone overlapping the resistive element, and extending a second distance away from the resistive element, wherein the zone is free of conductive material and the second distance is greater than the first distance.

Example 17: The system of example 16, wherein the resistance of the resistive element comprises a first resistance value in response to a first voltage at the conductive contact, and a second resistance value in response to a second voltage at the conductive contact, wherein the second voltage is higher than the first voltage, and wherein the second resistance value is higher than the first resistance value.

Example 18: The system of example 16 or example 17, further comprising a first trace comprising a first width in the first metallization layer, wherein the resistive element comprises a second trace in the first metallization layer comprising a second width, and the second width is less than the first width.

Example 19: An integrated circuit (IC) device comprising: electrostatic discharge (ESD) protection circuitry to protect first circuitry, wherein the ESD protection circuitry is coupled with a conductive contact at a surface of the IC device; a resistive element coupled between the conductive contact and the first circuitry, wherein a resistance of the resistive element comprises a first resistance value in response to a signal voltage at the conductive contact, and a second resistance value in response to a second voltage at the conductive contact, wherein the second voltage is greater than a signal voltage, and the second resistance value is higher than the first resistance value; a first dielectric layer adjacent to a first metallization layer comprising the resistive element, and a second metallization layer adjacent to the first dielectric layer, wherein a height of the first dielectric layer and the second metallization layer is a first distance; and a zone overlapping the resistive element, and extending a second distance away from the resistive element, wherein the zone is free of conductive material and the second distance is greater than the first distance.

Example 20: The IC device of example 19, further comprising a first trace comprising a first width in the first metallization layer, wherein the resistive element comprises a second trace in the first metallization layer comprising a second width, and the second width is less than the first width.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An integrated circuit (IC) device comprising:
a conductive contact at a surface of the IC device;
a resistive element coupled between the conductive contact and first circuitry;
second circuitry coupled between the resistive element and the conductive contact, wherein the second circuitry is further coupled with a supply line and comprises at least one of a diode or a power clamp;
a first metallization layer, wherein the resistive element is disposed in the first metallization layer;
a first dielectric layer adjacent to the first metallization layer, and a second metallization layer adjacent to the first dielectric layer, wherein a height of the first dielectric layer and the second metallization layer is a first distance; and
a zone overlapping the resistive element, and extending a second distance away from the resistive element, wherein the zone is free of conductive material and the second distance is greater than the first distance.

2. The IC device of claim 1, wherein a resistance of the resistive element increases in response to an electrostatic discharge (ESD) event to protect the first circuitry.

3. The IC device of claim 1, wherein a resistance of the resistive element comprises a first resistance value in response to a first voltage at the conductive contact, and a second resistance value in response to a second voltage at the conductive contact, wherein the second resistance value is higher than the first resistance value.

4. The IC device of claim 3, wherein the second voltage is greater than 2.5 volts and the second resistance value is about 7.2 ohms, and the first voltage is less than 2.0 volts and the first resistance value is about 3.1 ohms.

5. The IC device of claim 1, further comprising a first trace comprising a first width in the first metallization layer, wherein the resistive element comprises a second trace in the first metallization layer comprising a second width, and the second width is less than the first width.

6. The IC device of claim 1, further comprising a first trace and a second trace adjacent to the first trace in a same metallization layer, wherein the first trace is separated from the second trace by a third distance; and
wherein the resistive element comprises a third trace and a fourth trace adjacent to the third trace in the first metallization layer, wherein the third trace is separated from the fourth trace by a fourth distance, and the fourth distance is less than the third distance.

7. The IC device of claim 1, further comprising a third metallization layer adjacent to the first metallization layer and on a side of the first metallization layer opposite the second metallization layer, wherein the resistive element comprises a first trace in the first metallization layer and a second trace in the third metallization layer.

8. The IC device of claim 1, wherein the first circuitry comprises a transistor.

9. The IC device of claim 8, wherein a gate of the transistor is soft-coupled with a bulk and a substrate of the transistor is soft-coupled with the bulk.

10. The IC device of claim 1, wherein the supply line is a first supply line, the first circuitry comprises an output node and a component, and the component is coupled between the output node and at least one of the first supply line or a second supply line, wherein the component comprises at least one of an inductor, a capacitor, a resistor, or a transistor.

11. The IC device of claim 1, wherein the first circuitry comprises at least one of a switch, a receiver, a transmitter, an inverter, a serializer-deserializer, or an amplifier.

12. The IC device of claim 1, wherein the supply line is a first supply line, the second circuitry is to protect the first circuitry from an electrostatic discharge (ESD) event, and the power clamp is a first power clamp, the second circuitry comprising:
the first supply line;
a second supply line;
a first diode coupled between the conductive contact and the first supply line;
a second diode coupled between the conductive contact and the second supply line; and
a second power clamp coupled between the first supply line and the second supply line.

13. The IC device of claim 1, wherein the supply line is a first supply line, the second circuitry is to protect the first circuitry from an electrostatic discharge (ESD) event, and the power clamp is a first power clamp,
the second circuitry comprising:
the first supply line;
a second supply line; and
a second power clamp coupled between the conductive contact and at least one of the first supply line or the second supply line.

14. The IC device of claim 1, wherein the supply line is a first supply line, and the second circuitry is to protect the first circuitry from an electrostatic discharge (ESD) event, the second circuitry comprising:
the first supply line;
a second supply line;
a first diode comprising a first cathode coupled at a node with the conductive contact and a first anode coupled with the second supply line;
a second diode comprising a second anode coupled at the node with the conductive contact and a second cathode coupled with the second supply line; and
a first inductor coupled between the conductive contact and the node, and a second inductor coupled between the resistive element and the node.

15. The IC device of claim 1, wherein the zone comprises a portion of the first metallization layer laterally adjacent to the resistive element.

16. A system comprising:
a memory coupled with a microprocessor;
an integrated circuit (IC) device coupled with at least one of the memory or the microprocessor, wherein the IC device comprises:
electrostatic discharge (ESD) protection circuitry to protect first circuitry, wherein the ESD protection circuitry is coupled with a conductive contact at a surface of the IC device, and coupled with at least one of a first supply line to provide a first voltage or a second supply line to provide a ground reference voltage;
a resistive element coupled between the conductive contact and the first circuitry,
wherein a resistance of the resistive element increases in response to an ESD event to protect the first circuitry, and the resistive element is disposed in a first metallization layer;
a first dielectric layer adjacent to the first metallization layer, wherein a height of the first dielectric layer and the first metallization layer is a first distance; and
a zone overlapping the resistive element, and extending a second distance away from the resistive element, wherein the zone is free of conductive material and the second distance is greater than the first distance.

17. The system of claim 16, wherein the resistance of the resistive element comprises a first resistance value in response to a first voltage at the conductive contact, and a second resistance value in response to a second voltage at the conductive contact, wherein the second voltage is higher than the first voltage, and wherein the second resistance value is higher than the first resistance value.

18. The system of claim 16, further comprising a first trace comprising a first width in the first metallization layer, wherein the resistive element comprises a second trace in the first metallization layer comprising a second width, and the second width is less than the first width.

19. An integrated circuit (IC) device comprising:
electrostatic discharge (ESD) protection circuitry to protect first circuitry, wherein the ESD protection circuitry is coupled with a conductive contact at a surface of the IC device;
a resistive element coupled between the conductive contact and the first circuitry, wherein a resistance of the resistive element comprises a first resistance value in response to a signal voltage at the conductive contact, and a second resistance value in response to a second voltage at the conductive contact, wherein the second voltage is greater than a signal voltage, and the second resistance value is higher than the first resistance value;
a first dielectric layer adjacent to a first metallization layer comprising the resistive element, and a second metallization layer adjacent to the first dielectric layer, wherein a height of the first dielectric layer and the second metallization layer is a first distance; and
a zone overlapping the resistive element, and extending a second distance away from the resistive element, wherein the zone is free of conductive material and the second distance is greater than the first distance.

20. The IC device of claim 19, further comprising a first trace comprising a first width in the first metallization layer, wherein the resistive element comprises a second trace in the first metallization layer comprising a second width, and the second width is less than the first width.
